(19) United States
(12) Patent Application Publication
(10) Pub. No.: US 2025/0199401 A1
(43) Pub. Date: Jun. 19, 2025

(54) RESIN COMPOSITION, CURED PRODUCT, ELECTRONIC COMPONENT, AND DISPLAY DEVICE

(71) Applicant: TORAY INDUSTRIES, INC., Tokyo (JP)

(72) Inventors: Kenta AOSHIMA, Otsu-shi (JP); Keiko ICHINOSE, Nagoya-shi (JP); Hitoshi ARAKI, Otsu-shi (JP); Itaru ASANO, Nagoya-shi (JP); Yu SHOJI, Otsu-shi (JP); Tomoki SAKAI, Otsu-shi (JP)

(73) Assignee: TORAY INDUSTRIES, INC., Tokyo (JP)

(21) Appl. No.: 18/846,882

(22) PCT Filed: Mar. 14, 2023
(86) PCT No.: PCT/JP2023/009813

§ 371 Date: Sep. 13, 2024

(30) Foreign Application Priority Data
Mar. 23, 2022 (JP) 2022-046353

(51) Int. Cl. G03F 7/004; G03F 7/038; G03F 7/039; H10K 59/124

(52) U.S. Cl. CPC G03F 7/0045; G03F 7/0382; G03F 7/0387; G03F 7/0395; G03F 7/0397; H10K 59/124

(57) ABSTRACT

A resin composition including: (A) a soluble resin, (B) an organic salt, and (C) a solvent, wherein the (B) organic salt is an organic salt formed from an organic compound having a carboxy group and an organic compound having an amino group, and wherein the amount of the (B) organic salt is 0.01 to 10 parts by mass with respect to 100 parts by mass of (A) the soluble resin. Provided is a resin composition having excellent substrate adhesion and excellent storage stability.

### TECHNICAL FIELD

The present invention relates to: a soluble resin; a resin composition containing an organic salt and a solvent; a cured product obtained by curing the resin composition: an electronic component including the cured product; and a display device including the cured product.

### BACKGROUND ART

For surface protective films and interlayer insulating films of electronic components, materials such as polyimide materials and polybenzoxazole materials having excellent heat resistance, electrical insulation, and mechanical properties are widely used. In a process of producing an electronic component, a metal layer is formed on an insulating film in some cases. If adhesion between both of the films is insufficient, the films will be peeled from each other at the interface, causing the electronic component to have poor reliability. Accordingly, a material for use for an insulating film is desired to have excellent adhesion to a metal layer. When evaluated in a development stage, the material is desired to have excellent adhesion to a metal substrate.

With respect to this problem, a resin composition containing an additive such as a basic nitrogen containing compound or a thiol derivative is disclosed (see Patent Literature 1 to 3).

Additionally, to satisfy the requirements of the microfabrication necessary to achieve a higher degree of integration of an electronic component, a resin composition containing a photosensitizer so as to be patternable using a photolithography method is used for an insulating film in some cases. In this case, such a resin composition having fine pattern processability in the order of several microns to ten-odd microns is used suitably.

### CITATION LIST

### Patent Literature

Patent Literature 1: JP2007-39486A
Patent Literature 2: JP2003-5369A Patent Literature 3: WO2014/115233

### SUMMARY OF INVENTION

### Technical Problem

Resin compositions described in Patent Literature 1 and Patent Literature 3, when stored at room temperature, undergo promoted reaction of the resin, resulting in having an increased viscosity. A resin composition described in Patent Literature 2 has poor compatibility between the resin and additives. Hence, any of these resin compositions has a problem with storage stability.

In view of this, a problem to be addressed by the present invention is to provide a resin composition having excellent substrate adhesion and excellent storage stability.

### Solution to Problem

To solve the above-described problems, the present invention has the following constitutions. Thai is,
[1]A resin composition containing: (A) a soluble resin, (B) an organic salt, and (C) a solvent, wherein (B) the organic salt is an organic salt formed from an organic compound having a carboxy group and an organic compound having an amino group, and wherein the amount of (B) the organic salt is 0.01 to 10 parts by mass with respect to 100 parts by mass of (A) the soluble resin.
[2] The resin composition according to [1] wherein (B) the organic salt contains an organic salt having a structure represented by the formula (6) or the formula (7).

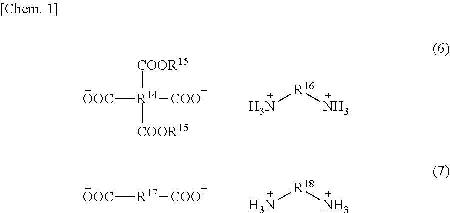

(In the formula (6), R¹⁴ represents a C₄₋₄₀ tetravalent organic group. R¹⁵ represents a hydrogen atom or a C₁₋₁₀ monovalent organic group. R¹⁶ represents a C₁₋₄₀ divalent organic group.)

(In the formula (7), R¹⁷ represents a C₁₋₄₀ divalent organic group with the proviso that R¹⁷ contains neither a carboxy group nor a carboxylic acid ester group. R¹⁸ represents a C₁₋₄₀ divalent organic group.)
[3] The resin composition according to [1] or [2], wherein (A) the soluble resin contains at least one soluble resin selected from the group consisting of a polyimide, a polybenzoxazole, a precursor thereof, or a copolymer thereof.
[4] The resin composition according to any one of [1] to [3], further containing (D) a photosensitizer.
[5] The resin composition according to any one of [1] to [4], wherein (A) the soluble resin contains at least one soluble resin selected from the group consisting of:
a polyimide having a structure represented by the formula (1);
a polybenzoxazole having a structure represented by the formula (3);
a polyimide precursor having a structure represented by the formula (4), wherein g in the formula (4) is 2;
a polybenzoxazole precursor having a structure represented by the formula (4), wherein g in the formula (4) is 0; or
a copolymer thereof.

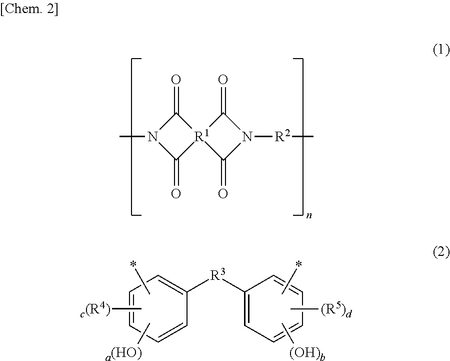

(In the formula (1), R¹ represents a C₄₋₄₀ tetravalent organic group. R² represents a structure represented by the formula (2).)

(In the formula (2), R³ represents a single bond, —O—, —C(CH₃)₂—, or —C(CF₃)—, and R⁴ and R⁵ represent a C₁₋₂₀ monovalent organic group a and b each independently represent an integer of 1 to 4, and c and d each independently represent an integer of 0 to 1. The sign * represents a chemical bond)

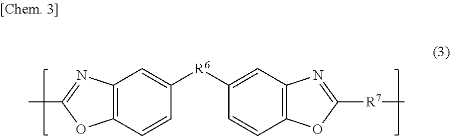

(In the formula (3), R⁶ represents a single bond, —O—, —C(CH₃)₂—, or —C(CF₃)₂—. R⁷ represents a C₄₋₄₀ divalent organic group.)

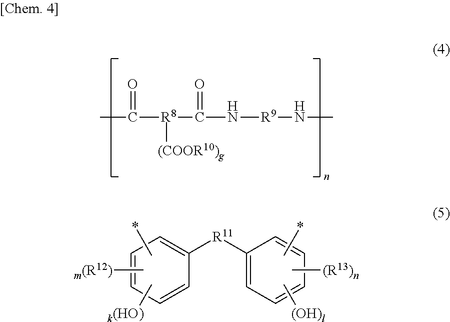

(In the formula (4), R⁸ represents a C₄₋₄₀ divalent to tetravalent organic group. R⁹ represents a structure represented by the formula (5), R¹⁰ represents a hydrogen atom or a C₁₋₂₀ monovalent organic group g represents 0 or 2.)

(In the formula (5), R¹¹ represents a single bond, —O—, —(CH₃)₂—, or —C(CF₃)₂—, and R¹² and R¹³ represent a C₁₋₂₀ monovalent organic group k and l each independently represent an integer of 1 to 4, and m and n each independently represent an integer of 0 to 1. The sign * represents a chemical bond.)
[6] The resin composition according to any one of [1] to [5], wherein R¹⁶ in the formula (6) and R¹⁸ in the formula (7) are each a structure represented by the formula (8).

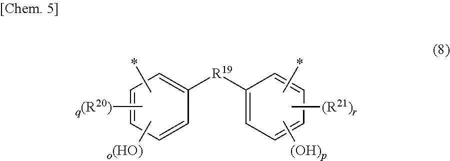

(In the formula (8), R¹⁹ represents a single bond, —O—, —C(CH₃)₂—, or —C(CF₃)₂—, and R²⁰ and R²¹ represent a C₁₋₂₀ monovalent organic group. o and p each independently represent an integer of 1 to 4, and q and reach independently represent an integer of 0 to 1. The sign * represents a chemical bond.)
[7] The resin composition according to 161, wherein R¹¹ in the formula (8) is C(CF₃)₂—
[8]A cured product obtained by curing the resin composition according to any one of [1] to [7].
[9] An electronic component including the cured product according to [8].
[10]A display device including the cured product according to [8].

### Advantageous Effects of Invention

The present invention provides a resin composition having excellent substrate adhesion and excellent storage stability. In an aspect further including a photosensitizer, a resin composition having fine pattern processability is provided.

### DESCRIPTION OF EMBODIMENTS

The present invention will be described in detail below.

### <(A) Soluble Resin>

The resin composition according to the present invention contains (A) a soluble resin. The soluble resin in the present invention refers to a resin 0.1 g or more of which is soluble in 100 g of an organic solvent or an aqueous alkali solution at 25° C.

Examples of the organic solvent include γ-butyrolactone, γ-valerolactone, δ-valerolactone, dimethyl sulfoxide, tetrahydrofuran, dioxane, propylene glycol monomethyl ether, propylene glycol monoethyl ether, acetone, methylethyl ketone, cyclopentanone, cyclohexanone, ethyl acetate, butyl acetate, isobutyl acetate, propyl acetate, propylene glycol monomethyl ether acetate, 3-methyl-3-nethoxybutyl acetate, methyl lactate, ethyl lactate, diacetone alcohol, 3-methyl-3-methoxy butanol, toluene, xylene, N-methyl-2-pyrrolidone, N-ethyl-2-pyrrolidone, N,N-dimethyl formamide, NAN-dimethyl acetamide, 1,3-dimethyl-2-imidazolidinone, N, N-dimethylpropyleneurea, 1,3-dimethylisobutylanide, methoxy-N,N-dimethylpropioneamide, and butoxy-N,N-dimethyIpropioneamide.

Examples of the aqueous alkali solution include an aqueous solution such as of tetramethylammoniutm hydroxide (TMAH), diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, or hexamethylenediamine.

Examples of (A) the soluble resin include polyimides, polyimide precursors, polybenzoxazoles, polybenzoxazole precursors, polyamides, polyamideimides, phenolic resins, acrylic resins, polyureas, polyesters, and polysiloxanes. In addition, two or more kinds of these resins may be contained in the resin composition Among these, at least one soluble resin selected from the group consisting of a polyimide, a poly benzoxazole, a precursor thereof, or a copolymer thereof is preferably contained from the viewpoint of having excellent heat resistance, strength. and substrate adhesion.

A polyimide and a polybenzoxazole are each a resin having a cyclic structure in its main chain structure, that is, they have an imide ring and an oxazole ring respectively. In addition, the precursors thereof, i.e., a polyimide precursor and a polybenzoxazole precursor are resins that, through dehydration ring closure, form an imide ring structure and a benzoxazole ring structure respectively.

A polyimide is obtained by allowing a tetracarboxylic acid, the corresponding tetracarboxylic dianhydride, a tetracarboxylate diester dichloride, or the like to react with a diamine, the corresponding disocyanate compound, a trimethylcisilylated diamine, or the like, and has an organic group derived from a tetracarboxylic acid and an organic group derived from a diamine. For example, a polyimide is obtained by allowing a polyamic acid to undergo dehydration ring closure through a heating treatment, in which the polyamic acid is a polyimide precursor, and obtained by allowing a tetracarboxylic dianhydride to react with a diamine. During this heating time, a solvent azeotropic with water, such as n-xylene, may be added. Alternatively, a polyimide is obtained by adding a dehydration condensation agent such as a carboxylic anhydride or dicyclohexylcarbodimide to a. ring closing catalyst such as a base, for example, a triethylamine, and allowing the resulting mixture to undergo dehydration ring closure through a chemical heat treatment. Alternatively, a polyimide is obtained by adding a weakly acidic carboxylic acid compound, and allowing the resulting mixture to undergo dehydration ring closure through a heating treatment at a low temperature of 100° C. or less.

A polybenzoxazole is obtained by allowing a bisaminophenol compound to react with a dicarboxylic acid, the corresponding dicarboxylic chloride, a dicarboxylic active ester, or the like, and has an organic group derived from a dicarboxylic acid and an organic group derived from a bisaminophenol. For example, a. polybenzoxazole is obtained by allowing a polyhydroxyamide to undergo dehydration ring closure through a heating treatment, in which the polyhydroxyamide is a polybenzoxazole precursor, and obtained by allowing a bisaminophenol compound to react with a dicarboxylic acid. Alternatively, a polybenzoxazole is obtained by adding a phosphoric anhydride, a base, a carbodimide compound, and the like, and allowing the resulting mixture to undergo dehydration ring closure through a. chemical treatment.

(A) the soluble resin preferably contains at least one soluble resin selected from the group consisting of: a polyimide having a structure represented by the formula (1); a polybenzoxazole having a structure represented by the formula (3); a polyimide precursor having a structure represented by the formula (4), wherein g in the formula (4) is 2; a polybenzoxazole precursor having a structure represented by the formula (4), wherein g in the formula (4) is 0; or a copolymer thereof. (A) the soluble resin contains at least one soluble resin selected from the group consisting of a polyimide having a structure represented by the formula (1); a polybenzoxazole having a structure represented by the formula (3); a polyimide precursor having a structure represented by the formula (4), wherein g in the formula (4) is 2; a polybenzoxazole precursor having a structure represented by the formula (4), wherein g in the formula (4) is 0; or a copolymer thereof. Because of this, the resin composition has excellent heat resistance, strength, and substrate adhesion, achieves a larger dissolution rate in an aqueous alkali solution as a developing solution, makes a larger difference between the dissolution rate of the hardened part of the coating film of the resin composition in a developing solution and the dissolution rate of the unhardened part in the developing solution (the difference is hereinafter referred to as a dissolution contrast, and obtains fine pattern processability.

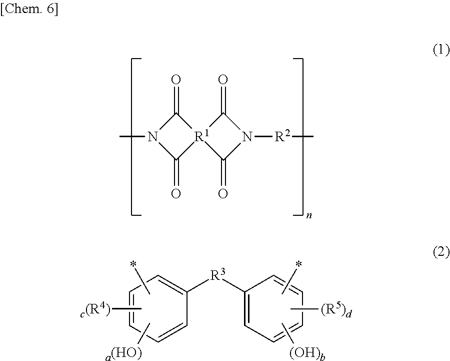

(In the formula (1), R¹ represents a C₄₋₄₀ tetravalent organic group, R² represents a structure represented by the formula (2).)

(In the formula (2), R represents a single bond, —O—, —C(CH₃)₂—, or —C(CF₃)₂—, and R⁴ and R⁵ represent a C₁₋₂₀ monovalent organic group. a and b each independently represent an integer of 1 to 4, and c and d each independently represent an integer of 0 to 1. The sign * represents a chemical bond.)

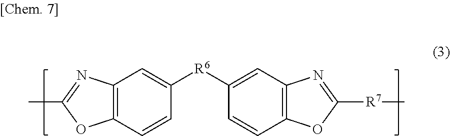

(In the formula (3), R⁶ represents a single bond, —O—, —C(CH)₂—, or —C(CF)₂—. R⁷ represents a C₄₋₄₀ divalent organic group.)

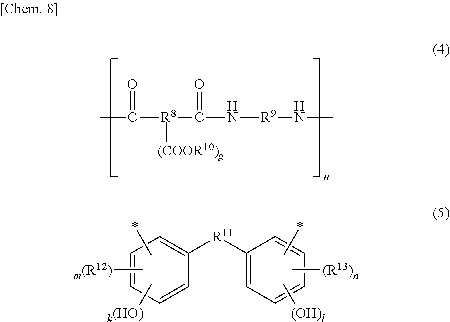

(In the formula (4), R⁸ represents a C₄₋₄₀ divalent to tetravalent organic group. R⁹ represents a structure represented by the formula (5), R¹⁰ represents a hydrogen atom or a C₁₋₂₀ monovalent organic group. g represents 0 or 2.)

(In the formula (5), R¹¹ represents a single bond, —O—, —C(CH₃)₂—, or —C(CF₃)₂—, and R¹¹ and R¹³ represent a C₁₋₂₀ monovalent organic group. k and l each independently represent an integer of 1 to 4, and m and n each independently represent an integer of 0 to 1. The sign * represents a chemical bond.)

R¹ in the formula (1) is an organic group derived from a C₄₋₄₀ tetravalent carboxylic acid or a derivative thereof, and is preferably an organic group derived from a tetracarboxylic dianhydride. Examples of the tetracarboxylic dianhydride include: aromatic tetracarboxylic dianhydrides such as pyromellitic dianhydride, 3,3′,4,4′-biphenyltetracarboxylic dianhydride, 2,3,3′,4′-biphenyltetracarboxylic dianhydride, 2,2′,3,3′-biphenyltetracarboxylic dianhydride, 3,3′,4,4′-benzophenone tetracarboxylic dianhydride, 2,2′,3,3%-benzophenone tetracarboxylic dianhydride, 2,2-bis(3,4-dicarboxyphenyl)propane dianhydride, 2,2-bis(2.3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl)sulfone dianhydride, 4,4′-oxydiphthalic anhydride, 1,2,5,6-naphthalene tetracarboxylic dianhydride, 9,9-bis(3,4-dicarboxyphenyl)fluorensic dianhydride, 9,9-bis {4-(3,4-dicarboxyphenoxy)phenyl}fluorensic dianhydride, 2,3,6,7-naphthalene tetracarboxylic dianhydride, 2,3,5,6-pyridine tetracarboxylic dianhydride, 3,4,9,10-perylene tetracarboxylic dianhydride, and 2,2-bis(3,4-dicarboxyphenyl)hexafluoropropane dianhydride; 3,3′,4,4′-diphenylsulfone tetracarboxylic dianhydride, 1,2,3,4-cyclobutane tetracarboxylic dianhydride, 1,2,3,4-cyclopentane tetracarboxylic dianhydride, 1,2,4,5-cyclohexane tetracarboxylie dianhydride, 5-(2,5-dioxotetrahydrofuryl)-3-methyl-3-cyclohexene-1,2-dicarboxylic dianhydride, 2,3,5-tricarboxy-2-cyclopentaneacetic dianhydride, 2,3,4,5-tetrahydrofuran tetracarboxylic dianhydride, 4-(2,5-dioxotetrahydrofuran-3-yl)-1,2,3,4-tetrahydronaphthalene-1,2-dicarboxylic dianlhydrde, 4-(15-dioxotetrahydrofuran-3-yl)-4 methyl-1,2,3,4-tetrahydronaphthalene-1,2-dicarboxylic dianhydride, 4-(2,5-dioxotetrahydrofuran-3-yl)-7 methyl-1,2,3,4-tetrahydronaphthalene-1,2-dicarboxylic dianhydride, norbornane-2-spiro-2′-cyclopentanone-5-spiro-2″-norbornane-5,5″,6,6″-tetracarboxyic dianhydride, norbomane-2-spiro-2′-cyclohexanone-6′-spiro-2″-norbornane-5,5″,6,6″-tetracarboxylic dianhydride; and compounds obtained by substituting part of hydrogen atoms of the aromatic rings or hydrocarbons of these dianhydrides with a C₁₋₁₀ alkyl group, a fluoroalkyl group, a halogen atom, or the like. In addition, these tetracarboxylic dianhydrides may be used in combination of two or more kinds thereof.

R² in the formula (1) is a structure represented by the formula (2). Examples of the diamine having a structure represented by the formula (2) include: bis(3-amino-4-hydroxyphenyl)ether, bis(3-amino-4-hydroxyphenyl)methylene, bis[N-(3-aminobenzoyl)-3-amino-4-hydroxyphenyl]sulfone, bis[-(4-aminobenzoyl)-3-amino-4-hydroxyphenyl]-sulfone, bis(3-amino-4-hydroxyphenyl)sulfone, bis(3-amino-4-hydroxyphenyl)propane, 2,2′-bis[N-(3-aminobenzoyl)-3-amino-4-hydroxyphenyl]propane, 2,2′-bis[N-(4-aminobenzoyl)-3-amino-4-hydroxyphenyl]propane, 9,9-bis(3-amino-4-hydroxyphenyl)fluorene, 9,9-bis[N-(-aminobenzoyl)-3-amino-4-hydroxyphenyl]fluorene, 9,9-bis[N-(4-aminobenzoyl)-3-amino-4-hydroxyphenyl]fluorene, N,N′-bis(3-aminobenzoyl)-2,5-diamino-1,4-dihydroxybenzene, N,N′-bis(4-aminobenzoyl)-2,5-diamino-1,4-dihydroxybenzene, N,N′-bis(4-aminobenzoyl)-4,4′-diamino-3,3-dihydroxybiphenyl, N,N′-bis(3-aminobenzoyl)-3,3′-diamino-4,4-dihydroxybiphenyl, N,N′-bis(4-aminobenzoyl)-3,3′-diamino-4,4-dihydroxybiphenyl, 3,3′-diamino-4,4′-biphenol, bis(3-amino-4-hydroxyphenyl)methane, 1,1-bis(3-amino-4-hydroxyphenyl)ethane, 2,2-bis(3-amino-4-hydroxyphenyl)propane, and 12-bis(3-amino-4-hydroxyphenyl)hexafluoropropane; and compounds obtained by substituting part of hydrogen atoms of the aromatic rings or hydrocarbons of these diarnines with a C₁₋₁₀ alkyl group, a fluoroalkyl group, a halogen atom, or the like. In addition, these diamines having a structure represented by the formula (2) may be used in combination of two or more kinds thereof.

R⁶ in the formula (3) represents a single bond, —O—, —C(CH₃)₂—, or —C(CF₃)₂—.

R⁷ in the formula (3) represents a C₄₋₄₀ divalent organic group. R⁷ in the formula (3) is an organic group derived from a C₄₋₄₀ divalent carboxylic acid or a derivative thereof, and is preferably an organic group derived from a dicarboxylic acid.

Examples of the dicarboxylic acid include: phthalic acid, isophthalic acid, terephthalic acid, 2,2′-biphenyldicarboxylic acid, 3,4′-biphenyldicarboxylic acid, 4,4′-biphenyldicarboxylic acid, benzophenone-2,4′-dicarboxylic acid, benzophenone-4,4′-dicarboxylic acid, 2,2-bis(4-carboxyphenyl)hexafluoropropane, 3,3′-dicarboxydiphenyl ether, 3,4′-dicarboxydiphenyl ether, 4,4′-dicarboxydiphenyl ether, 3,3′-dicarboxydiphenyl methane, 3,4′-dicarboxydiphenyl methane, 4,4′-dicarboxydiphenyl methane, 3,3′-dicarboxydiphenyl difluoromethane, 3,4′-dicarboxydiphenyl difluoromethane, 4,4′-dicarboxydiphenyl difluoromethane, 3,3′-dicarboxydiphenyl sulfone, 3,4′-dicarboxydiphenyl sulfone, 4,4′-dicarboxydiphenyl sulfone, 3,3′-dicarboxydiphenyl sulfide, 3,4′-dicarboxydiphenyl sulfide, 4,4′-dicarboxydiphenyl sulfide, 3,3′-dicarboxydiphenyl ketone. 3,4′-dicarboxydiphenyl ketone. 4,4′-dicarboxydiphenyl ketone, 2,2-bis(3-carboxyphenyl)propane, 2,2-bis(3,4′-dicarboxyphenyl)propane, 2,2-bis(4-carboxyphenyl)propane, 2,2-bis(3-carboxyphenyl)hexafluoropropane, 2,2-bis(3,4′-carboxyphenyl)hexafluoropropane, 2,2-bis(4-carboxyphenyl)hexafluoropropane, 1,3-bis(3-carboxy-phenoxy)benzene, 1,4-bis(3-carboxyphenoxy)benzene, and 1,3-bis(4-carboxyphenoxy)benzene; and compounds obtained by substituting part of hydrogen atoms of the aromatic rings or hydrocarbons of these dicarboxylic acids with a C₁₋₁₀ alkyl group, a fluoroalkyl group, a halogen atom, or the like. In addition, these dicarboxylic acids nay be used in combination of two or more kinds thereof.

R⁸ in the formula (4) represents a C₄₋₄₀ divalent to tetravalent organic group. When g is 0 in the formula (4), R¹ in the formula is an organic group derived from a C₄₋₄₀ divalent carboxylic acid or a derivative thereof, and is preferably an organic group derived from a dicarboxylic acid.

Examples of the dicarboxylic acid include the same examples as given for R⁷ in the formula (3).

When g is 2 in the formula (4), R¹ in the formula is an organic group derived from a C₄₋₄₀ tetravalent carboxylic acid or a derivative thereof, and is preferably an organic group derived from a tetracarboxylic dianhydride,

Examples of the tetracarboxylic dianhydride include the same examples as given for R¹ in the formula (1).

R⁹ in the formula (4) is a structure represented by the formula (5). Examples of the diamine having a structure represented by the formula (5) include the same examples as given for a structure represented by the formula (2).

In (A) the soluble resin, a terminal thereof is preferably end capped with any one or more of a monoamine, acid anhydride, acid chloride, and monocarboxylic acid. With the end capped with any one or more of a monoamine, acid anhydride, acid chloride, and monocarboxylic acid, the resin composition has excellent storage stability.

When the terminal is capped with a monoamine, the amount of the monoamine is preferably in the range of from 0.1 to 60 mol %, more preferably from 5 to 50 mol %, with respect to all the amine components. The amount is preferably 5 mol % or more from the viewpoint of excellent storage stability, and preferably 50 mol % or less from the viewpoint of affording a sufficient weight average molecular weight.

Examples of the monoamine include 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphithalene, 2-carboxy-6-aminonaphtbalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 3-amino-4,6-dihydroxypyrimidine, 2-aminophenol, 3-aminophenol, 4-aminophenol, 2-aminothiophenol, 3-aminothiophenol, and 4-aminothiophenol. These monoamines may be used in combination of two or more kinds thereof.

When the terminal is capped with an acid anhydride, acid chloride or monocarboxylic acid, the amount of each compound is preferably in the range of from 0.1 to 60 mol %, more preferably from 5 to 50 mol %, with respect to all the acid components. The amount is preferably 5 mol % or more from the viewpoint of excellent storage stability, and preferably 50 mol % or less from the viewpoint of affording a sufficient weight average molecular weight.

Examples of the acid anhydride, the acid chloride, and the monocarboxylic acid include: acid anhydrides such as phthalic anhydride, maleic anhydride, nadic anhydride, cyclohexanedicarboxylic anhydride, and 3-hydroxyphthalic anhydride; monocarboxylic acids such as 3-carboxyphenol, 4-carboxyphenol, 3-carboxythiophenol 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene. and 1-mercapto-5-carboxynaphthalene, and monoacid chloride compounds obtained by converting a carboxy group of such a monocarboxylic acid into an acid chloride; monoacid chloride compounds obtained by converting only one carboxy group of a dicarboxylic acid into an acid chloride, wherein examples of the dicarboxylic acid include terephthalic acid, phthalic acid, maleic acid, cyclohexanedicarboxylic acid, 1,5-dicarboxynaphthalene, 1,6-dicarboxynaphthalene, 1,7-dicarboxynaphthalene, and 2.6-dicarboxynaphthalene; and active ester compounds produced by allowing a monoacid chloride compound react with, N-hydroxybenzotriazole or N-hydroxy-5-norbomene-2,3-dicarboximide. These acid anhydrides, acid chlorides, and monocarboxylic acids may be used in combination of two or more kinds thereof.

(A) the soluble resin preferably has a weight average molecular weight of 1,000 or more and 200,000 or less, more preferably 5,000 or more and 100,000 or less, still more preferably 10,000 or more and 50,000 or less. Having a weight average molecular weight in the range makes it possible to obtain fine pattern processability, heat resistance, and strength. The weight average molecular weight is measured using a gel permeation chromatography method (GPC method), and calculated in terms of polystyrene.

### <(B) Organic Salt>

The resin composition according to the present invention contains (B) an organic salt. The organic salt in the present invention refers to a salt formed from an organic compound having an acidic functional group and an organic compound having a basic functional group. Examples of the acidic functional group include a carboxy group, sulfonic acid group, phosphate group, and phenolic hydroxyl group. Examples of the basic functional group include amino groups, specifically primary amino groups and secondary amino groups.

(B) the organic salt preferably contains an organic salt having a structure represented by the formula (6) or the formula (7). (B) the organic salt containing an organic salt having a structure represented by the formula (6) or the formula (7) makes it possible to further enhance the adhesion between the resin composition and a substrate such as a Si substrate, SiO₂ substrate, SiN substrate, Al substrate, Cu substrate, Ti substrate, or ITO substrate.

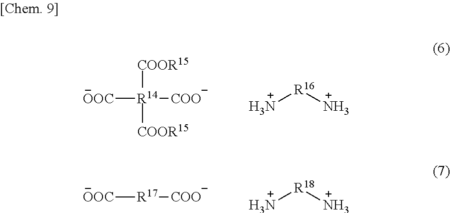

(In the formula (6), R¹⁴ represents a C₄₋₄₀ tetravalent organic group. R¹⁵ represents a hydrogen atom or a C₁₋₁₀ monovalent organic group. R¹⁶ represents a C₁₋₄₀ divalent organic group.)

(In the formula (7), R¹⁷ represents a C₁₋₄₀ (divalent organic group with the proviso that R¹⁷ contains neither a carboxy group nor a carboxylic acid ester group. R¹⁸ represents a C₁₋₄₀ divalent organic group.)

R¹⁴ in the formula (6) is an organic group derived from a C₄₋₄₀ tetravalent carboxylic acid or a derivative thereof, and is preferably an organic group derived from a tetracarboxylic acid.

Examples of the tetracarboxylic acid include: aromatic tetracarboxylic acids such as pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenone tetracarboxylic acid, 2,2′,3,3-benzophenone tetracarboxylic acid, 2,2-bis(3,4-dicarboxy phenyl)propane, 2,2-his(2,3-dicarboxyphenyl)propane, 1,1-bis(3,4-dicarboxyphenyl)ethane, 1,1-his(2,3-dicarboxyphenyl)ethane, his(3.4-dicarboxyphenyl)methane, bis(2,3-dicarboxyphenyl)methane, bis(3,4-dicarboxyphenyl)sulfone, 4,4′-oxydiphthalic acid, 1,2,5,6-naphthalene tetracarboxylic acid, 9,9-bis(3,4-dicarboxyphenyl)fluorensic acid, 9,9-bis {4-(3,4-dicarboxyphenoxy)phenyl}fluorensic acid, 2,3,6,7-naphthalene tetracarboxylic acid, 2,3,5,6-pyridine tetracarboxylic acid, 3,4,9,10-perylene tetracarboxylic acid, and 2,2-bis(3,4-dicarboxyphenyl)hexafluoropropane, 3,3′,4,4′-diphenylsulfone tetracarboxylic acid, 1,2,3,4-cyclobutane tetracarboxylic acid, 1,2,3,4-cyclopentane tetracarboxylic acid, 1,2,4,5-cyclohexane tetracarboxyic acid, 5-(2,5-dioxotetrahydrofuryl)-3-methyl-3-cyclohexene-1,2-dicarboxylic acid, 2,3,5-tricarboxy-2-cyclopentaneacetic acid, 2,3,4,5-tetrahydrofuran tetracarboxylic acid, 4-(2,5-dioxo tetrahydrofuran-3-yl)-1,2,3,4-tetrahydronaphthalene-1,2-dicarboxylic acid, 4-(2,5-dioxo tetrahydrofuran-3-yl)-4 methyl-1,2,3,4-tetrahydronaphthalene-1,2-dicarboxylic acid, 4-(2,5-dioxo tetrahydrofuran-3-yl)-7 methyl-1,2,3,4-tetrahydronaphthalene-1,2-dicarboxylic acid, norbornane-2-spiro-2′-cyclopentanone-5′-spiro-2″-norbornane-5,5″,6,6″-tetracarboxylic acid, norhomane-2-spiro-2′-cyclohexanone-6′-spiro-2″-norbormane-5,5″,6,6″-tetracarboxylic acid; and compounds obtained by substituting part of hydrogen atoms of the aromatic rings or hydrocarbons of these tetracarboxylic acids with a C₁₋₁₀ alkyl group, a fluoroalkyl group, a halogen atom, or the like. In addition, these tetracarboxylic acids may be used in combination of two or more kinds thereof.

R¹⁶ in the formula (6) is an organic group derived from a C₁₋₄₀ divalent diamine or a derivative thereof, and is preferably a divalent organic group obtained by removing two amino groups from a diamine.

Examples of the diamine include: aromatic diamines such as 3.4′-diaminodiphenyl ether, 4,4′-diaminodiphenyl ether, 3,4′-diaminodiphenyl methane, 4,4′-diaminodiphenyl methane, 3,4-diaminodiphenyl sulfone, 4,4′-diaminodiphenyl sulfone, 3,4′-diaminodiphenyl sulfide, 4,4′-diaminodiphenyl sulfide, 1.4-bis(4-aminophenoxy)benzene, benzine, n-phenylene diamine, p-phenylene diamine, 1,5-naphthalene diamine, 2.6-naphthalene diamine, bis(4-aminophenoxyphenyl)sulfone, bis(3-aminophenoxyphenyl)sulfone, bis(4-aminophenoxy)biphenyl, bis{4-(4-aminophenoxy)phenyl} ether, 1,4-bis(4-aminophenoxy)benzene, 2,2′-diethyl-4,4′-diaminobiphenyl, 2,2′-diethyl-4,4′-diaminobiphenyl 1,3,3′-dimethyl-4,4′-diaminobiphenyl, 3,3′-diethyl-4,4′-diaminobiphenyl, 2,2′,3,3′-tetramethyl-4,4′-diaminobiphenyl, 3.3′,4,4′-tetramethyl-4,4′-diaminobiphenyl. 2,2′-bis(trifluoromethyl)-4,4′-diaminobiphenyl, compounds obtained by substituting pail of hydrogen atoms of the aromatic rings or hydrocarbons of these aromatic dianines with a C₁m alkyl group, a fluoroalkyl group, a halogen atom, or the like; and bis(3-amino-4-hydroxyphenyl)ether, bis(3-amino-4-hydroxyphenyl)methylene, bis[N-(3-aminobenzoyl)-3-amino-4-hydroxyphenyl]sulfone, bis[N-(4-aminobenzoyl)-3-amino-4-hydroxyphenyl]sulfone, bis(3-amino-4-hydroxyphenyl)sulfone, bis(3-amino-4-hydroxyphenyl)propane, 2,2′-bis[N-(3-aminobenzoyl)-3-amino-4-hydroxyphenyl]propane, 2,2′-bis[N-(4-aminobenzoyl)-3-amino-4-hydroxyphenyl]propane. 9,9-bis(3-amino-4-hydroxyphenyl)fluorene, 9,9-bis[A-(3-aminobenzoyl)-3-amino-4-hydroxyphenyl]fluorene, 9,9-bis[N-(4-aminobenzoyl)-3-amino-4-hydroxy phenyl]fluorene, N,N′-bis(3-aminobenzoyl)-2,5-diamino-1,4-dihydroxybenzene, N,N′-bis(4-aminobenzoyl)-2,5-diamino-1,4-dihydroxy benzene, N,N′-bis(4-aminohenzol)-44′-diamino-3,3-dihydroxybiphenyl, N,N′-bis(3-aminobenzoyl)-3,3′-diamino-4,4-dihydroxybiphenyl, N,N′-bis(4-aminobenzoyl)-3,3′-diamino-4,4-dihydroxybiphenyl, 3,3′-diamino-4,4′-biphenol, bis(3-amino-4-hydroxyphenyl)methane, 1,1-bis(3-amino-4-hydroxyphenyl)ethane, 2,2-bis(3-amino-4-hydroxyphenyl)propane, 2,2-bis(3-amino-4-hydroxyphenyl)hexafluoropropane, and compounds obtained by substituting part of hydrogen atoms of the aromatic rings or hydrocarbons of these diamines with a C₁₋₁₀ alkyl group, a fluoroalkyl group, a halogen atom, or the like.

R¹⁷ in the formula (7) represents a C₁₋₄₀ divalent organic group. R¹⁷ in the formula (7) is an organic group derived from a C₁₋₄₀ divalent carboxylic acid or a derivative thereof, and is preferably an organic group derived from a dicarboxylic acid.

Examples of the dicarboxylic acid include: phthalic acid, isophthalic acid, terephthalic acid, 2,2′-biphenyldicarboxylic acid, 3,4′-biphenyldicarboxylic acid, 4,4-biphenyldicarboxylic acid, benzophenone-2,4′-dicarboxylic acid, benzophenone-4,4′-dicarboxylic acid, 2,2-bis(4-carboxyphenyl)hexafluoropropane, 3,3′-dicarboxydiphenyl ether, 3,4′-dicarboxydiphenyl ether, 4,4′-dicarboxydiphenyl ether, 3,3′-dicarboxydiphenyl methane, 3,4′-dicarboxydiphenyl methane, 4,4′-dicarboxydiphenyl methane, 3,3-dicarboxydiphenyl difluoromethane, 3,4′-dicarboxydiphenyl difluoroethane, 4,4′-dicarboxydiphenyl difluoromethane, 3,3′-dicarboxydiphenyl sulfone, 3,4′-dicarboxydiphenyl sulfone, 4,4′-dicarboxydiphenyl sulfone, 3,3′-dicarboxydiphenyl sulfide, 3,4′-dicarboxydiphenyl sulfide, 4,4′-dicarboxydiphenyl sulfide, 3,3′-dicarboxydiphenyl ketone, 3,4′-dicarboxydiphenyl ketone, 4,4′-dicarboxydiphenyl ketone, 2,2-bis(3-carboxyphenyl)propane, 2,2-bis(3,4′-dicarboxyphenyl)propane, 2,2-bis(4-carboxyphenyl)propane, 2,2-bis(3-carboxyphenyl)hexafluoropropane, 2,2-bis(3,4′-carboxyphenyl)hexafluoropropane, 2,2-bis(4-carboxyphenyl)hexafluoropropane. 1,3-bis(3-carboxyphenoxy)benzene, 1,4-bis(3-carboxyphenoxy)benzene, and 1,3-bis(4-carboxy phenoxy)benzene; and compounds obtained by substituting part of hydrogen atoms of the aromatic rings or hydrocarbons of these dicarboxylic acids with a C₁₋₁₀ alkyl group, a fluoroalkyl group, a halogen atom, or the like. In addition, these dicarboxylic acids may be used in combination of two or more kinds thereof.

R¹⁸ in the formula (7) is an organic group derived from a C₁₋₄₀ divalent diamine or a derivative thereof, and is preferably a divalent organic group obtained by removing two amino groups from a diamine.

Examples of the diamine include the same examples as given for R¹⁶ in the formula (6).

R¹⁶ in the formula (6) and R¹⁸ in the formula (7) are each preferably a structure represented by the formula (8). Having a structure represented by the formula (8) results in achieving a larger dissolution rate in an aqueous alkali solution as a. developing solution, achieving a. larger dissolution contrast between the hardened part and unhardened part of the coating film of the resin composition, and making it easier to obtain fine pattern processability.

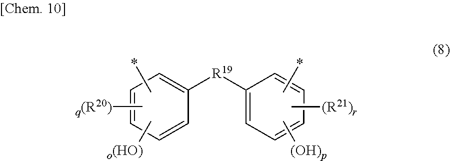

(In the formula (8), R¹⁹ represents a single bond, —O—, —C(CH₃)₂—, or —C(CF₃)₂—, and R²⁰ and R²¹ represent a C₁₋₂₀ monovalent organic group. o and p each independently represent an integer of 1 to 4; q and r each independently represent an integer of 0 to 1. The sign * represents a chemical bond.)

Examples of the diamine having a structure represented by the formula (8) include bis(3-amino-4-hydroxyphenyl)ether, bis(3-amino-4-hydroxyphenyl)methylene, bis[N-(3-aminobenzoyl)-3-amino-4-hydroxyphenyl]sulfone, bis[N-(4-aminobenzoyl)-3-amino-4-hydroxyphenyl]-sulfone. bis(3-anno-4-hydroxy phenyl)sulfone, bis(3-amino-4-hydroxyphenyl)propane, 2,2′-bis[IN-(3-aminobenzoyl)-3-amino-4-hydroxyphenyl]propane, 2,2′-bis[N-(4-aminobenzoyl)-3-amino-4-hydroxyphenyl]propane, 9,9-bis(3-amino-4-hydroxyphenyl)fluorene, 9,9-bis[N-(3-aminobenzoyl)-3-amino-4-hydroxyphenyl]fluorene, 9,9-bis[V-(4-aminobenzoyl)-3-amino-4-hydroxyphenyl]fluorene, N,N′-his(3-aminobenzoyl)-2,5-diamino-1,4-dihydroxybenzene, N-bis(4-aminobenzoyl)-2,5-diamino-1,4-dihydroxybenzene, N,N-bis(4-aminobenzoyl)-4,4′-diamino-3,3-dihydroxybiphenyl, N,N′-bis(3-aminobenzoyl)-3,3′-diamino-4,4-dihydroxybiphenyl, N,N′-bis(4-aminobenzoyl)-3,3′-diamino-4,4-dihydroxybiphenyl, 3,3′-diamino-4,4′-biphenol, bis(3-amino-4-hydroxyphenyl)methane, 1,1-bis(3-amino-4-hydroxyphenyl)ethane, 2,2-bis(3-amino-4-hydroxyphenyl)propane, 2,2-bis(3-amino-4-hydroxyphenyl)hexafluoropropane, and compounds obtained by substituting part of hydrogen atoms of the aromatic rings or hydrocarbons of these diamines with a C₁₋₁₀ alkyl group, a fluoroalkyl group, a halogen atom, or the like.

R¹⁹ in the formula (8) is more preferably —C(CF₃)₂—. R¹⁹ being —C(CF₃)₂-results in achieving a larger dissolution rate in an aqueous alkali solution as a developing solution, achieving a larger dissolution contrast between the hardened part and unhardened part of the coating film of the resin composition, and making it easier to obtain fine pattern processability, than R¹¹ being a. single bond, —O—, or —C(CH₃)₂—.

Examples of the diamine containing —C(CF₃)₂— as R¹⁹ in the formula (8) include 2,2-bis(3-amino-4-hydroxyphenyl)hexafluoropropane and compounds obtained by substituting part of hydrogen atoms of the aromatic rings or hydrocarbons of these diamines with a C₁₋₁₀ alkyl group, a fluoroalkyl group, a halogen atom, or the like.

The amount of (B) the organic salt is 0.01 part by mass or more and 10 parts by mass or less, preferably 0.05 part by mass or more and 1 part by mass or less, with respect to 100 parts by mass of (A) the soluble resin. Having (B) the organic salt in an amount of less than 0.01 part by mass causes the fine pattern processability and the substrate adhesion to be poorer. Having (B) the organic salt in an amount of more than 10 parts by mass causes the storage stability to be poorer.

Among (B) the organic salts, an organic salt having a structure represented by the formula (6) is obtained, for example, by stirring the tetracarboxylic acid and the diamine in equimolar amounts in a solvent, and an organic salt having a structure represented by the formula (7) is obtained, for example, by stirring the dicarboxylic acid and the diamine in equimolar amounts in a solvent.

Examples of the solvent include: organic solvents enumerated in the section <(A) Soluble Resin>; and water. The solvent is more preferably water from the viewpoint of a reaction yield. The reaction temperature is preferably 0° C. or more and 150° C. or less, more preferably 10° C. or more and 120° C. or less, particularly preferably 30° C. or more and 80° C. or less. Having the reaction temperature within the preferable range makes it possible that the tetracarboxylic acid and the diamine react sufficiently to afford an organic salt having a structure represented by the formula (6), among (B) the organic salts, and that overreaction is inhibited. In addition, having the reaction temperature makes it possible that the dicarboxylic acid and the diamine react sufficiently to afford an organic salt having a structure represented by the formula (7), among (B) the organic salts, and that overreaction is inhibited. The reaction time is preferably 0.5 hours or more and 30 hours or less, more preferably 1 hour or more and 20 hours or less, particularly preferably 2 hours or more and 10 hours or less. Having the reaction time within the preferable range makes it possible that the tetracarboxylic acid and the diamine react sufficiently to afford an organic salt having a structure represented by the formula (6), among (B) the organic salts, and that overreaction is inhibited. In addition, having the reaction time makes it possible that the dicarboxylic acid and the diamine react sufficiently to afford an organic salt having a structure represented by the formula (7), among (B) the organic salts, and that overreaction is inhibited.

A second embodiment in which an organic salt having a structure represented by the formula (6), among (B) the organic salts, is obtained is, for example, a method as follows: a tetracarboxylic anhydride as a derivative of the tetracarboxylic acid is stirred in water to be hydrolyzed; then, the diamine in an equimolar amount is added; and the resulting mixture is stirred. The reaction temperature for the hydrolysis is preferably 0° C. or more and 150° C. or less, more preferably 10° C. or more and 120° C. or less, particularly preferably 30° C. or more and 80° C. or less. Having the reaction temperature within the preferable range makes it possible that the hydrolysis progresses sufficiently, and that overreaction is inhibited. The reaction time is preferably 0.5 hours or more and 30 hours or less, more preferably 1 hour or more and 20 hours or less, particularly preferably 2 hours or more and 10 hours or less. Having the reaction temperature within the preferable range makes it possible that the hydrolysis progresses sufficiently, and that overreaction is inhibited.

### <(C) Solvent>

A resin composition according to the present invention contains (C) a solvent. The solvent in the present invention refers to a component in which (A) the soluble resin, (B) the organic salt, (D) the photosensitizer, and another component can be dissolved.

The amount of (C) the solvent is not particularly limited, and is preferably 100 parts by mass or more and 10,000 parts by mass or less, more preferably 100 parts by mass or more and 5,000 parts by mass or less, still more preferably 100 parts by mass or more and 2,000 parts by mass or less, with respect to 100 parts by mass of (A) the soluble resin. Having the amount of (C) the solvent within the preferable range makes it possible to form a coating film having excellent film formability and coating film flatness, and having a thickness of 1 μm or more.

The boiling point of (C) the solvent under atmospheric pressure is preferably 50° C. or more and 250° C. or less, more preferably 100° C. or more and 210° C. or less. Having the boiling point within the range under atmospheric pressure makes it possible to remove the solvent from the coating film in a short time in a process of drying the coating film of the resin composition, and to achieve excellent step embedding ability on a patterned substrate. Examples of the solvent having a boiling point within the range under atmospheric pressure include: ethyl lactate (the boiling point, 154° C.); butyl lactate (the boiling point, 186° C.); alkylene glycol monoalkyl ethers such as dipropylene glycol dimethyl ether (the boiling point, 171° C.), diethylene glycol dimethyl ether (the boiling point, 162° C.), diethylene glycol ethyl methyl ether (the boiling point, 176° C.), diethylene glycol diethyl ether (the boiling point, 189° C.), 3-methoxybutyl acetate (the boiling point, 171° C.), ethylene glycol monoethyl ether acetate (the boiling point, 160° C.), γ-butyrolactone (the boiling point, 203° C.), N-methyl-2-pyrrolidone (the boiling point, 204° C.), diacetone alcohol (the boiling point, 166′C), N-cyclohexyl-2-pyrrolidone (the boiling point, 154° C.), N,N-dimethyl formamide (the boiling point, 153° C.), N,N-dimethyl acetamide (the boiling point, 165° C.), dimethyl sulfoxide (the boiling point, 189° C.), propylene glycol monomethyl ether acetate (the boiling point, 146° C.), N,N-dimethyl isobutyramide (the boiling point, 175° C.), ethylene glycol monomethyl ether (the boiling point, 124° C.), and propyleneglycol monomethyl ether (the boiling point, 120° C.); alkyl acetates such as propyl acetate (the boiling point, 102° C.), butyl acetate (the boiling point, 125° C.), and isobutyl acetate (the boiling point, 118° C.); ketones such as methylisobutyl ketone (the boiling point, 116° C.), and methylpropyl ketone (the boiling point, 102° C.); and alcohols such as butyl alcohol (the boiling point, 117° C.) and isobutyl alcohol (the boiling point, 108° C.). These solvents having a boiling point of 100° C. or more and 210° C. or less under atmospheric pressure may be used in combination of two or more kinds thereof.

The solubility parameter (SIP value) of (C) the solvent is preferably 7.0 or more and 13.0 or less. Having the SP value within the range can inhibit precipitation of solid, and makes (A) the soluble resin more dissolvable. The SP value is more preferably 12.5 or less. The solubility parameter (SP value) used in the present invention is a value stated in the literature “Basic Science of Coating” (Yuji Harazaki; Maki Shoten; p. 65). In addition, a value used for a solvent having no SP value in the literature is a value determined by calculation from the evaporation energy and molar volume of an atom and an atomic group, wherein the evaporation energy and molar volume are values according to Fedors, and are described in page 55 of the same literature, Examples of the solvent having an SP value of 7.0 or more and 13.0 or less include ethyl lactate (the SP value, 10.6, a value in the literature), butyl lactate (the SP value, 9.7, a value in the literature), dipropylene glycol dimethyl ether (the SP value, 7.9, a calculated value), diethylene glycol dimethyl ether (the SP value, 8.1, a calculated value), diethylene glycol ethyl methyl ether (the SP value, 8.1, a calculated value), diethylene glycol diethyl ether (the SP value, 8.2, a calculated value), 3-methoxybutyl acetate (the SP value, 8.7, a calculated value), ethylene glycol monoethyl ether acetate (the SP value, 9.0, a calculated value), γ-butyrolactone (the SP value, 12.8, a value in the literature), N-methyl-2-pyrrolidone (the SP value, 11.2, a value in the literature), diacetone alcohol (the SP value, 10.2, a value in the literature), N-cyclohexyl-2-pyrrolidone (the SP value, 10.8, a value in the literature), N,N-dimethyl formamide (the Sp value, 12.1, a value in the literature), N,N-dimethyl acetamide (the SF value, 11.1. a value in the literature), dimethyl sulfoxide (the SP value, 12.9, a value in the literature), propylene glycol monomethyl ether acetate (the SP value, 8.7, a calculated value), N,N-dimethyl isobutyramide (the SP value, 9.9, a calculated value), ethylene glycol monomethyl ether (the SP value, 10.8, a calculated value), propylene glycol monomethyl ether (the SF value, 10.2, a calculated value), propyl acetate (the SF value, 8.7, a calculated value), butyl acetate (the SP value, 8.5, a value in the literature), isobutyl acetate (the SP value, 8.4, a value in the literature), methylisobutyl ketone (the SP value, 8.6, a value in the literature), methylpropyl ketone (the SP value, 8.9, a calculated value), butyl alcohol (the SF value, 11.3. a value in the literature), and isobutyl alcohol (the SP value, 11.1, a value in the literature). These solvents having an SF value of 7.0 or more and 13.0 or less may be used in combination of two or more kinds thereof.

### <(D) Photosensitizer>

A resin composition according to the present invention contains (D) a photosensitizer. A photosensitizer in the present invention refers to a component that generates a reactive species through exposure, and is (D-1) a photoacid generator, (D-2) a photoinitiator, or the like.

(D-1) the photoacid generator is a component that generates acid through exposure, and thus increases the dissolution rate of the exposed area in an aqueous alkali solution, bringing about a dissolution contrast with the unexposed area. and thus producing a positive type relief pattern in which the exposed area is solubilized. The positive type is preferably selected particularly in applications that require a high resolution. In addition, containing (D-1) the photoacid generator and the below-described crosslinking agent allows the acid generated in the exposed area to facilitate the crosslinking reaction of a crosslinking agent, thus producing a negative type relief pattern in which the exposed area is insolubilized. The negative type is preferably selected particularly in applications that require high exposure sensitivity and/or thick film processing.

Examples of (D-1) the photoacid generator include quinone diazide compounds, sulfonium salts, phosphonium salts, diazonium salts, and iodonium salts.

Examples of the quinone diazide compound include: a compound in which a polyhydroxy compound and a sulfonyl group of a quinone diazide are bound via an ester bond; a compound in which a polyamino compound and a sulfonyl group of a quinone diazide are bound via a sulfone amide bond; and a compound in which a polyhydroxy polyamino compound and a sulfonyl group of a quinone diazide are bound via an ester bond and/or a sulfone amide bond.

As the sulfonyl group of the quinone diazide compound, any of a 4-naphthoquinone diazide sulfonyl group and a 5-naphthoquinone diazide sulfonyl group is used preferably. The 4-naphthoquinone diazide sulfonyl ester compound has an absorption in the i-line range of a mercury lamp, and is suitable for i-line exposure. The 5-naphthoquinone diazide sulfonyl ester compound has an absorption in the g-line range of a mercury lamp, and is suitable for g-line exposure. In the present invention, it is preferable that a 4-naphthoquinone diazide sulfonyl ester compound or a 5-naphthoquinone diazide sulfonyl ester compound is selected, depending on the wavelength of light used for exposure. In addition, the resin composition may contain a naphthoquinone diazide sulfonyl ester compound containing a 4-naphthoquinone diazide sulfonyl group and a 5-naphthoquinone diazide sulfonyl group in the same molecule, or may contain a 4-naphthoquinone diazide sulfonyl ester compound and a 5-naphthoquinone diazide sulfonyl ester compound.

Among (D-1) the photoacid generators, sulfonium salts, phosphonium salts, diazonium salts, and iodonium salts are preferable from the viewpoint of suitably stabilizing the acid generated through exposure. Among these, sulfonium salts are more preferable from the viewpoint of wiring corrosion.

Examples of the cation that forms a sulfonium salt include: triarylsulfoniums such as triphenylsulfonium, tri-p-tolylsulfoniurn, tri-o-tolylsulfonium, tris(4-methoxyphenyl)sulfonium, 1-naphthyldiphenylsulfoniurn, 2-naphthyldiphenylsulfonium, tris(4-fluorophenyl)sulfonium, tri-1-naphthylsulfonium, tri-2-naphthylsulfoniun, tris(4-hydroxyphenyl)sulfonium, 4-(phenylthio)phenyldiphenylsulfonium, 4-(p-tolvithio)phenyldi-o-tolylsulfonium, 4-(4-methoxyphenylthio)phenylbis(4-methoxyphenyl)suilfoniurn, 4-(phenylthio)phenylbis(4-fluorophenyl)sulfoniun, 4-(phenylthio)phenylbis(4-methoxyphenyl)sulfonium, 4-(phenylthio)phenyldi-p-tolyisulfonium, [4-(4-biphenylylthio)phenyl]-4-biphenylylphenylsulfoniurn, [4-(2-thioxanthonylthio)phenyl]diphenylsulfoitmi, bis[4-(diphenylsulfonio)phenil sulfide, bis[4-1bis 4-(2-hydroxyethoxy)pheil]sulfonio phenyl]sulfide, his{4-[bis(4-fluorophenyl)sulfonio]phenyl}sulfide, bis{4-[bis(4-methylphenyl)sulfonio]phenyl}sulfide, bis{4-[bis(4-methoxyphenyl)sulfonio]phenyl} sulfide, 4-(4-benzoyl-2-chlorophenylthio)phenylbis(4-fluorophenyl)sulfonium 4-(4-benzoyl-2-chlorophenylthio)phenyldiphenylsulfoniun, 4-(4-benzoylphenylthio)phenylbis(4-fluorophenyl)sulfonium, 4-(4-benzoylpheny lthio)phenyldiphenylsulfonium, 7-isopropyl-9-oxo-10-thia-9,10-dihydroanthracene-2-yldi-p-tolylsulfoniun, 7-isopropyl-9-oxo-10-thia-9,I0-dihy droanttracene-2-yl-diphenylsulfonium, 2-[(di-p-tolyl)sulfonio]thioxanthone, 2-[(diphenyl)sulfoniolthioxanthone, 4-(9-oxo-911-thioxanthene-2-yl)thiophenyl-9-oxo-9H-thioxanthene-2-vlphenylsulfonium, 4-[4-(4-tert-butylbenzoyl)phenylthio]pheniyldi-p-tolylsulfoniun, 4-[44-tert-butylbenzoyl)phenylthio]phenyldiphenylsulfoniurn, 4-[4-(benzoylphenylthio)]phenyldi-p-tolylsulfonium, 4-[4-(benzoyiphenylthio)]phenyldiphenylsulfoniun, 5-(4-methoxyphenyl)thia anthrenium, 5-phenylthia anthreniumr, 5-tolylthia anthreniurn, 5-(4-ethoxyphenyl)thia anthreniurn, and 5-(2,4,6-trirethylphenyl)thia anthreniurn, diary]sulfoniums such as diphenilphenacylsulfonium-. diphenyl 4-nitrophenacylsulfoniulm diphenylbenzylsulfonium, and diphenylrmethylsulfoniurn; and monoarylsulfoniurns such as phenylrethylbenzylsulfonrium, 4-hydroxyphenylmethylbenzylsulfoniurn, 4-rnethoxyphenylmethylbenzyisulfoniun, 4-acetocarbonvioxyphenylmethylbenzyisulfoniun, 4-hydroxyphenyl(2-naphthylmethyl)methylsulfonium, 2-naphthylmmethylbenzylsulfonium, 2-naphthylmethyl(1-ethoxycarbonyl)ethylsulfonium, phenylrmethylphenacylsulfonium, 4-hydroxyphenylmethylphenacvlsulfonium, 4-methoxyphenylimethylphenacylsulfonium, 4-acetocarbonyloxyphenylrmethylphenaeylsulfonium, 2-naphthylmethylphenacylsulfonium, 2-naphthyloctadecylphenacyl sulfoniun, and 9-anthracenylmethylphenacylsulfonium; dimethylphenacylsulfoniurn, phenacyltetrahydrothiopheniun, dimethylbenzyisulfoniurn, benzyltetrahydrothiopheniun, and octadecvImethylphenacylsulfonium.

As the anion that forms a sulfonium salt, at least one selected from the group consisting of a borate ion, phosphate ion, or gallate ion is preferably contained.

Examples of the borate ion include pentafluorophenyl borate, trifluorophenyl borate, tetrafluorophenyl borate, trifluoromethylphenyl borate, bis(trifluoromethyl)phenyl borate, pentafluoroethylphenyl borate, bis(pentafluoroethyl)phenyl borate, fluoro-bis(trifluoromethyl)pheil borate, fluoro-pentafluoroethylphenyl borate, and fluoro-bis(pentafluoroethyl)phenyl borate.

Examples of the phosphate ion include hexafluorophosphate and tris(pentafluoroethyl)trifluorophosphate.

Examples of the gallate ion include tetrakis(pentafluorophenyl)gallate and tetrakis(3,5-his(trifluoromethyl)phenyl)gallate.

The amount of (D-1) the photoacid generator is preferably 0.01 part by mass or more and 50 parts by mass or less with respect to 100 parts by mass of (A) the soluble resin. The amount within the range is preferable from the viewpoints of good sensitivity and excellent storage stability.

(D-2) the photoinitiator is a component that undergoes bond cleavage and/or reaction through exposure to generate radicals. Containing (D-2) the photoinitiator and the below-described radical polymerizable compound results in facilitating the radical polymerization reaction in the exposed area to afford a negative type relief pattern in which the exposed area is insolubilized. The negative type is preferably selected particularly in applications that require high exposure sensitivity and/or thick film processing.

Examples of (D-2) the photoinitiator include a benzylketal-based photoinitiator, a-hydroxyketone-based photoinitiator, α-aminoketone-based photoinitiator, acylphosphine oxide-based photoinitiator, oxime ester-based photoinitiator, acridine-based photoinitiator, titanocene-based photoinitiator, benzophenone-based photoinitiator, acetophenone-based photoinitiator, aromatic ketoester-based photoinitiator, and benzoate ester-based photoinitiator. Among these, an α-amino ketone-based photoinitiator, acylphosphine oxide-based photoinitiator, and oxime ester-based photoinitiator are preferable from the viewpoint of sensitivity

Examples of the α-amino ketone-based photoinitiator include 2-methyl-1-[4-(methylthio)phenyl]-2-morpholinopropane-1-one, 2-benzyl-2-dimethylamino-1-(4-morpholinophenyl)-butane-1-one, 2-dimethylamino-2-(4-methylbenzyl)-1-(4-morpholinophenyl)-butane-1-one, and 3,6-bis(2-methyl-2-morpholinopropionyl)-9-octyl-9H-carbazole.

Examples of the acylphosphine oxide-based photoinitiator include 2,4,6-trimethylbenzoyl-diphenylphosphine oxide, bis(2,4,6-trimethylbenzoyl)-phenylphosphine oxide, and bis(2,6-dimethoxy benzoyl)-(2,4,4-trimethylpentyl)phosphine oxide,

Examples of the oxime ester-based photoinitiator include 1-phenylpropane-1,2-dione-2-(O-ethoxycarbonyl)oxime, 1-phenylbutane-1I2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-(carboxyphenyl)thio]phenyl]propane-1,2-dione-2-(O-acetyl)oxime, 1-[9-ethyl-6-(2-methylbenzoyl)-91-carbazole-3-yl]ethaoe-1-(O-acetyl)oxime, 1-[9-ethyl-6-[2-methyl-4-[1-(2,2-dimethyl-1,3-dioxolane-4-yl)methyloxy]benzoyl]-9H-carbazole-3-yl]ethanone-1-(O-acetyl)oxime, and 1-(9-ethyl-6-nitro-9H-carbazole-3-yl)-1-[2-methyl-4-(1-methoxypropane-2-yloxy)phenyl]methanone-1-(O-acetyl)oxime.

The amount of (D-2) the photoinitiator is preferably 1 part by mass or more and 25 parts by mass or less with respect to 100 parts by mass of (A) the soluble resin. The amount within the range is preferable from the viewpoints of good sensitivity and excellent resolution.

(D-1) the photoacid generator and (D-2) the photoinitiator in (D) the photosensitizer may each be used singly, or may be used in combination. The amount of (D) the photosensitizer is preferably 0.01 part by mass or more and 50 parts by mass or less with respect to 100 parts by mass of (A) the soluble resin. The amount within the range is preferable from the viewpoints of good sensitivity and excellent resolution and storage stability.

### <Crosslinking Agent>

A resin composition according to the present invention may further contain a crosslinking agent. The crosslinking agent in the present invention refers to a component that crosslinks (A) the soluble resin or another component, and is, for example, a compound having at least two functional groups of alkoxymethyl groups, methylol groups, epoxy groups, oxetanyl groups, or the like. Containing a crosslinking agent makes it possible to crosslink (A) the soluble resin or another component to enhance the heat resistance, strength, and chemical resistance of a cured film. In addition, containing the crosslinking agent and (D-1) the photoacid generator allows the acid generated in the exposed area to facilitate the crosslinking reaction of the crosslinking agent, thus producing a negative type relief pattern in which the exposed area is insolubilized.

Examples of the compound having at least two alkoxymethyl groups or methylol groups include: DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PITBP, DMOM-MBPC, TriML-P, TriML-35XL, TML-HQ, TML-BP, TML-pp-3PF, TML-BPE, TiML-BPA. T ML-BPAF, TML-BPAP, TMOM-BP, TMOM-BPE, TMOM-BPA, TMOM-BPAF, TMOM-BPAP, HML-TPPHBA, -ML-TPHAP, HMOM-TPPHBA, and HMOMTPHAP (which are trade names, manufactured by Honshu Chemical Industry Co., Ltd.); and “NIKALAC” (registered trademark) MX-290, “NIKALAC” MX-280, “NIKAL AC” MX-270, “NIKALAC” MX-279, “NIKALAC” MW-100LM, and “NIKAL AC” MX-750LM (which are trade names, manufactured by Sanwa Chemical Co., Ltd.). These compounds having at least two alkoxymethyl groups or methylol groups may be used in combination of two or more kinds thereof.

Examples of the compound having at least two epoxy groups include, “Epolite” (registered trademark) 40E, “Epolite” IOOE, “Epolite” 200E, “Epolite” 400E, “Epolite” 70P, “Epolite” 200P, “Epolite” 400P, “Epolite” 1500NP, “Epolite” 80MF, “Epolite” 4000, and “Epolite” 3002 (which are manufactured by Kyoeisha Chemical Co., Ltd.); “Denacol” (registered trademark) EX-212L, “Denacol” EX-2141, “Denacol” EX-21 6L, and “Denacol” EX-850L (which are manufactured by Nagase ChemteX Corporation); GAN and GOT (which are manufactured by Nippon kay aku Co., Ltd.); “Epicoat” (registered trademark) 828, “Epicoat” 1002, “Epicoat” 1750, “Epicoat” 1007, YX8100-BIH30, E1256, E4250, and E4275 (which are manufactured by Japan Epoxy Resin Co., Ltd.); “Epiclon” (registered trademark) EXA-9583 and HP4032 (which are manufactured by DIC Corporation); VG3101 (manufactured by Mitsui Chemicals, Inc.): “TEPIC” (registered trademark) S, “TEPIC” C, and “TEPIC” P (which are manufactured by Nissan Chemical Corporation); “Denacol” EX-32IL (manufactured by Nagase ChemteX Corporation), NC6000 (manufactured by Nippon Kayaku Co., Ltd.); “EPOTOHTO” (registered trademark) YH-434L (manufactured by Tohto Kasei Co, Ltd.); EPPN502H4 and NC3000 (manufactured by Nippon Kayaku Co., Ltd.); and “Epiclon” (registered trademark) N695 and HP7200 (which are manufactured by DIC Corporation). These compounds having at least two epoxy groups may be used in combination of two or more kinds thereof.

Examples of the comnpound having at least two oxetanyl groups include ETERNACOLL EHO, ETERNACOLL OXBP, ETERNACOLL OXTP, and ETERNACOLL OXMA (which are manufactured by Ube Industries, Ltd.). These compounds having at least two oxetanyl groups may be used in combination of two or more kinds thereof.

The amount of the crosslinking agent is preferably 5 parts by mass or more and 100 parts by mass or less, more preferably 10 parts by mass or more and 90 parts by mass or less, with respect to 100 parts by mass of (A) the soluble resin. The amount in the preferable range results in affording good chemical resistance and excellent heat resistance strength.

### <Radical Polymerizable Compound>

A resin composition according to the present invention may further contain a radical polymerizable compound. The radical polymerizable compound in the present invention refers to a component that undergoes a polymerization reaction through a radical mechanism. Containing a radical polymerizable compound and (D-2) the photoinitiator results in facilitating a radical polymerization reaction in the exposed area to afford a negative type relief pattern in which the exposed area is insolubilized.

Examples of the radical polymerizable compound include trimethylolpropane tri(meth)acrylate, ditrimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, 2,2-bis[4-(3-(meth)acryloxy-2-hydroxypropoxy)phenyl]propane, 1,3,5-tris((meth)acrloxyethyl)isocyanuric acid, 1,3-bis((meth)acryloxyethyl)isocyanuric acid 9,9-bis[4-(2-(meth)acryloxyethoxy)phenyl]fluorene, 9,9-bis[4-(3-(methl)acnloxypropoxy)plhenyl]florene, 9.9-bis(4-(meth)acrvloxyphenyl)fluorene, and acid modified products, ethylene oxide modified products, and propylene oxide modified products thereof. These radical polymerizable compounds may be used in combination of two or more kinds thereof.

The amount of the radical polymerizable compound is preferably 10 parts by mass or more and 90 parts by mass or less, more preferably 20 parts by mass or more and 80 parts by mass or less, with respect to 100 parts by mass of (A) the soluble resin. The amount in the preferable range results in affording good sensitivity and excellent heat resistance strength.

### <Solubility Promoter>

A resin composition according to the present invention may further contain a solubility promoter. The solubility promoter in the present invention refers to a component that enhances the solubility of the resin composition in an aqueous alkali solution. Containing a solubility promoter results in achieving a larger dissolution rate in an aqueous alkali solution as a developing solution, achieving a larger dissolution contrast between the hardened part and unhardened part of the coating film of the resin composition, and making it easier to obtain fine pattern processability.

Examples of the solubility promoter include phenol compounds such as: Bis-Z, BisOC-Z, BisOPP-Z, BisP-CP, Bis26X-Z, BisOTBP-Z, BisOCHP-Z, BisOCR-CP, BisP-MlZ, BisP-EZ, Bis26X-CP, BisP-PZ, BisP-IPZ, BisCRiPZ, BisOCP-IPZ, BisOIPP-CP, Bis26X-IPZ, BisOTBP-CP, TekP-41-IBPA (TetrakisP-DO-BPA), TrisP-HAP, TrisP-PA, TrisP-PHBA, TrisP-SA, TrisOCR-PA, BisOFP-Z, BisRS-2P, BisPG-26X, BisRS-3P, BisOC-OCHP, BisPC-OCHP, Bis25X-OCHP, Bis26X-OCHP, BisOCHP-OC. Bis236T-OCHP, methylene tris-PR-CR, BisRS-26X, and BisRS-OCHP (which are trade names, manufactured by Honshu Chemical Industry Co., Ltd.); BIR-OC, BTIP-PCBIR-PC, BIR-PTBP, BTR-PCHP, BIP-BIOC-F. 4PC, B1IR-BIPC-F, and TEP-BIP-A (which are trade names, manufactured by Asahi Yukizai Corporation); and 1,4-dihydroxynaphthalene, 1,5-dihydroxynaphthalene, 1,6-dihydroxynaphthalene, 1,7-dihydroxynaphthalene, 2,3-dihydroxynaphthalene, 2,6-dihydroxynaphthalene, 2,7-dihydroxynaphthalene, 2,4-dihydroxyquinoline, 2,6-dihydroxyquinolie, 2,3-dihydroxyquinoxaline, anthracene-1,2,10-triol, anthracene-1,8,9-triol, and 8-quinolinol. These solubility promoters may be used in combination of two or more kinds thereof.

The amount of the solubility promoter is preferably 1 part by mass or more and 20 parts by mass or less with respect to 100 parts by mass of (A) the soluble resin. The amount in the preferable range results in affording good heat resistance and fine pattern processability.

### <Adhesion Improve Reagent>

A resin composition according to the present invention may further contain an adhesion improve reagent. The adhesion improve reagent in the present invention refers to a component that increases adhesion between a resin composition film and a substrate.

Examples of the substrate include Si substrates, SiO₂ substrates, SiN substrates, Al substrates, Cu substrates, Ti substrates, and ITO substrates.

2′5 Examples of the adhesion improve reagent include: silane coupling agents such as vinyltrimethoxysilane, vinyltriethoxysilane, epoxycyclohexvlethyltrimethoxysilane, 3-glvcidoxypropyltrimethoxysilane, 3-glycidoxypropylirethoxysilane, p-styryltrimethoxysilane, 3-aminopropyltrimethoxysilane, 3-aminopropyltriethoxysilane, and N-phenyl-3-aminopropyltrimethoxysilane; a titanium chelating agent and an aluminum chelating agent; and a compound obtained by allowing an aromatic amine compound to react with an alkoxy-group-containing silicon compound. These adhesion improve reagents may be used in combination of two or more kinds thereof.

The amount of the adhesion improve reagent is preferably 0.1 part by mass or more and 10 parts by mass or less with respect to 100 parts by mass of the total amount of the resin composition excluding (C) the solvent.

### <Surfactant>

A resin composition according to the present invention may further contain a surfactant. The surfactant in the present invention refers to a component that increases wettability between the resin composition and an underlying substrate. Examples of the surfactant include acryl-based and/or methacryl-based surfactants such as: SH series, SD series, and ST series of Toray Dow Coning Co., Ltd.: BYK series of BYK Japan KK; KP series of Shin-Etsu Chemical Co., Ltd.; DISFOAM series of NOF Corporation: “MEGAFAC (registered trademark)” series of DIC Corporation: FL UORAD series of Sumitomo 3M Limited; “SURFLON (registered trademark)” series and “ASA-TGUARD (registered trademark)” series of AGC Inc.: fluorine-based surfactants, such as POLYFOX series, of Omnova Solutions Inc.: POLYFLOW series of Kyoeisha Chemical Co.. Ltd.; and “DISPARLON (registered trademark)” series of Kusumoto Chemicals, Ltd.

The amount of the surfactant is preferably 0.001 part by mass or more and 1 part by mass or less with respect to 100 parts by mass of the total amount of the resin composition excluding (C) the solvent.

### <Cured Product>

A cured product according to the present invention is a cured product obtained by curing the resin composition, and may be a cured product in any form, subject to being a product obtained by curing the resin composition with light or heat. Examples of the method of curing with light include a method of curing through exposure at 50 mJ or more and 3,000 mJ or less with the 365 mu i-line, 405 nm h-line, or 432 nm g-line of a high-pressure mercury lamp. Examples of the method of curing with heat include a method of curing under heat treatment at 150° C. or more and 500° C. or less for 5 minutes or more and 5 hours or less.

A method of producing the cured product includes: a step of applying the resin composition to a substrate, and drying the resin composition to form a resin film on the substrate; a step of exposing the resin composition film to light; a step of removing an unexposed area or an unexposed area from the resin composition film with a developing solution to develop the resin composition film; and a step of heating the resin composition film after development to cure the resin composition film.

Examples of the step of applying the resin composition to a substrate, and drying the resin composition to form a resin film on the substrate include a step of applying the resin composition to a substrate using a spin coater, spray coater, screen coater, blade coater, die coater, calendar coater, meniscus coater, bar coater, roll coater, comma roll coater, gravure coater, slit die coater, or the like, and drying the resin composition in the range of 50° C. or more and 150° C. or less for 1 minute or more and 24 hours or less to form a resin composition film.

Examples of the step of exposing the resin composition film to light include a step of exposing the resin composition at 50 mJ or more and 3,000 mj or less with the 365 nm i-line, 405 nm h-line, or 432 nm g-line of a high-pressure mercury lamp via a mask having a desired pattern. The resin composition film exposed in the step may be baked after the exposure. The post exposure bake is performed preferably at 50° C. or more from the viewpoints of curability and adhesion to a substrate, and preferably at 150° C. or less from the viewpoint of resolution.

Examples of the step of removing an unexposed area or an unexposed area from the resin composition film with a developing solution to develop the resin composition film include: a step of spraying a developing solution on a face of the resin composition film; a step of building up a developing solution on a face of the resin composition film; a step of immersing the resin composition film in a developing solution; and a step of immersing the resin composition film in a developing solution, and ultrasonicating the resin composition film. Developing conditions such as a developing time, a developing step, and a developing solution temperature may be conditions under which the unexposed area or the exposed area can be removed to form a pattern. After the development, a rinsing treatment is preferably performed. The rinsing treatment is preferably performed with the following: water: alcohol such as ethanol or isopropyl alcohol; liquid supplemented with ethyl lactate or propylene glycol monomethyl ether acetate: or a combination of two or more thereof.

Examples of the step of heating the resin composition film after development to cure the resin composition include a step of heating the resin composition at 150° C. or more and 500° C. or less for 5 minutes or more and 5 hours or less to produce a cured product. The heating treatment can be selected from: a method in which a. temperature is selected, and raised in stages; and a method in which a. temperature range is selected, in which range the temperature is continuously raised. The former is, for example, a method in which a heat treatment is performed at 130° C. and 200° C. each for 30 minutes. The latter is, for example, a method in which the temperature is raised from room temperature to 400° C. in 2 hours.

### <Electronic Component>

An electronic component according to the present invention includes the above-described cured product. The cured product can be used as an insulating film, a. protective film, or the like that is a constituent of the electronic component.

Specific examples of the electronic component include: active components having a semiconductor, such as transistors, diodes, integrated circuits (ICs), and memories; and passive components such as resistors, capacitors, and inductors. Specific examples of the cured product in the electronic component include cured products suitably used for the following applications: a passivation film of a semiconductor; a semiconductor element, a surface protective film such as a thin film transistor (TFT); an interlayer insulating film such as an interlayer insulating film between redistributions in a 2-layer to 10-layer multilayer wiring for high density mounting; an insulating film and a protective film for a touch panel display, and an insulating layer of an organic electroluminescent device. The cured product may have any kind of structure other than these.

### <Display Device>

A display device according to the present invention includes the above-described cured product. The cured product can be used as a planarization layer or a pixel division layer that is a constituent of the display device.

The display device is, for example, an organic EL display device having a planarization layer, 1st electrode, pixel division layer, organic EL layer, and 2nd electrode on a substrate, in which the planarization layer and/or the pixel division layer contain(s) a cured product according to the present invention. For example, an active matrix type display device includes: a substrate, such as a sheet of glass or a resin film, on which there are a TFT (thin-film transistor) and wiring that is located on a lateral portion of the TFT, and connected to the TFT; a planarization layer provided on the substrate to cover the irregular surface; and a display element further provided on the planarization layer. The display element and the wiring are connected via a contact hole formed in the planarization layer. A cured product obtained by curing a photosensitive resin composition according to the present invention has excellent flatness and pattern-dimension stability, and thus, is preferably used for a planarization layer. In particular, making an organic EL display device flexible has been the mainstream in recent years. In such an organic EL display device, a substrate having the above-described driving circuit may be composed of a resin film.

### EXAMPLES

The present invention will be illustrated below with reference to Examples, but it should be understood that the present invention is not construed as being limited thereto. First, the evaluation method in each of Examples and Comparative Examples will be described.

(1) Evaluation of fine pattern processability of negative type resin composition containing (D-2) photoinitiator

A negative type resin composition containing (D-2) the photoinitiator was applied to a copper substrate using a spin coater (111-360S, manufactured by Mikasa Co., Ltd.), and dried by heating at 100° C. for 3 minutes using a hot plate (SCW-636, manufactured by Dainippon Screen Mfg, Co., Ltd.) to form a 10 μm coating film. This copper substrate having the coating film formed thereon was exposed at 200 mJ/cm² with an ultrahigh-pressure mercury lamp as a light source, via a photomask having a 30 μm/30 μm (=L/S) pattern, a 20 μm/20 μm pattern, and a 15 μm/15 μm pattern, using an aligner (PLA-501F, manufactured by Canon Inc.). The illuminance at 365 nm was measured and used to calculate the amount of exposure. Then, the coating film was heated at 120° C. for 1 minute, developed with 2 paddles for 45 seconds using an aqueous solution of 2.38 mass % tetrarmethylamnonium hydroxide (TMAH) as a developing solution, and using an automatic developing machine (AD-1200, manufactured by Takizawa Sangyo K.K.), and rinsed with pure water for 30 seconds. Then, the patterned portion was observed using an FPD microscope (MX61, manufactured by Olympus Corporation) to examine the smallest processable pattern size. The fine pattern processability was evaluated on the basis of the below-described criteria. Here, being processable means that the opening dimensions of the pattern after development corresponds to 95% or more of the dimensions of the pattern of the photomask. A and B were rated pass, and C was rated fail.
A: the smallest pattern size was 15 μm.
B: the smallest pattern size was 20 μm.
C: the smallest pattern size was 30 μm.
   (2) Evaluation of fine pattern processability of positive type resin composition containing (D-1) photoacid generator

A positive type resin composition containing (D-1) the photoacid generator was applied to a copper substrate using a spin coater (AH-360S. manufactured by Mikasa Co., Ltd), and dried by heating at 100° C. for 3 minutes using a hot plate (SCW-636, manufactured by Dainippon Screen Mfg. Co., Ltd.) to form a 10 urn coating film. This copper substrate having the coating film formed thereon was exposed at 800 mi/cm² with an ultrahigh-pressure mercury lamp as a light source, via a photomask having a 15 μm/15 μm(=L/S) pattern, a 10 μm/10 μm pattern, and a 5 μm/5 μm pattern, using an aligner (PLA-501F, manufactured by Canon Inc.). The illuminance at 365 nm was measured and used to calculate the amount of exposure. Then, the coating film was developed with 2 paddles for 45 seconds using an aqueous solution of 2.38 mass % tetramethylammonium hydroxide (TMAH) as a developing solution, and using an automatic developing machine (AD-1200, manufactured by Takizawa Sangyo K.K.), and rinsed with pure water for 30 seconds. Then, the patterned portion was observed using an FPD microscope (MX61, manufactured by Olympus Corporation) to examine the smallest processable pattern size. The fine pattern processability was evaluated on the basis of the below-described criteria. Here, being processable means that the opening dimensions of the pattern after development corresponds to 95% or more of the dimensions of the pattern of the photomask. A and B were rated pass, and C was rated fail.
A: the smallest pattern size was 5 μm.
B: the smallest pattern size was 10 μm.
C: the smallest pattern size was 15 μm.
   (3) Evaluation of fine pattern processability of negative type resin composition containing (D-1) photoacid generator

A negative type resin composition containing (D-1) the photoacid generator was applied to a copper substrate using a spin coater (111-360S, manufactured by Mikasa Co.. Ltd.), and dried by heating at 120° C. for 3 minutes using a hot plate (SCW-636, manufactured by Dainippon Screen Mfg. Co., Ltd.) to form a 15 Lim coating film. This copper substrate having the coating film formed thereon was exposed at 500 mJ/cm² with an ultrahigh-pressure mercury lamp as a light source, via a photomask having a 15 μm/15 μm (=L/S) pattern, a. 10 μm/10 μm pattern, and a 5 μm/5 μm pattern, using an aligner (PLA-501F, manufactured by Canon Inc.). The illuminance at 365 nm was measured and used to calculate the amount of exposure. Then, the coating film was heated at 100° C. for 3 minutes, developed with 2 paddles for 30 seconds using an aqueous solution of 2.38 mass % tetramethylammonium hydroxide (TMAH) as a developing solution, and using an automatic developing machine (AD-1200, manufactured by Takizawa Sangvo K. K.) and rinsed with pure water for 30 seconds. Then, the patterned portion was observed using an FPD microscope (MX61, manufactured by Olympus Corporation) to examine the smallest processable pattern size. The fine pattern processability was evaluated on the basis of the below-described criteria. Here, being processable means that the opening dimensions of the pattern after development corresponds to 95% or more of the dimensions of the pattern of the photomask. A to C were rated pass, and D was rated fail.
A: the smallest pattern size was 5 min.
B: the smallest pattern size was 10 μm.
C: the smallest pattern size was 15 am.
D: a pattern size of 15 μm was not achieved by processing.
   (4) Evaluation of substrate adhesion of non-photosensitive resin composition

A non-photosensitive resin composition was applied to a copper substrate using a spin coater (1H-360S, manufactured by Mikasa Co., Ltd.), and dried by heating at 100° C. for 3 minutes using a hot plate (SCW-636, manufactured by Dainippon Screen Mfg. Co., Ltd.) to form a 10 μm coating film. This copper substrate having the coating film formed thereon was heated to 280° C. at a heating rate of 3.5° C./minute at an oxygen concentration of 20 ppm or less, using an inert oven (CLH-21CD-S. manufactured by Koyo Thermo Systems Co., Ltd,), and then heated for 1 hour. In accordance with the cross-cut method in the JIS K5400-8.5 standard, the resulting cured film was incised with a grid of 10 columns and 10 rows, each 2 mm wide, using a single edged knife, and underwent a peeling test using a cellophane adhesive tape. The substrate adhesion was evaluated on the below-described criteria. A and B were rated pass, and C, D, and E were rated fail.
A: the number of the squares of the cured film that were adhering to the substrate after the test was 100.
B: the number of the squares of the cured film that were adhering to the substrate after the test was 80 or more and less than 100.
C: the number of the squares of the cured film that were adhering to the substrate after the test was 50 or more and less than 80.
D: the number of the squares of the cured film that were adhering to the substrate after the test was 20 or more and less than 50.
E: the number of the squares of the cured film that were adhering to the substrate after the test was less than 20.
   (5) Evaluation of substrate adhesion of negative type resin composition containing (D-2) photoinitiator

A negative type resin composition containing (D-2) the photoinitiator was applied to a copper substrate using a spin coater (1H-360S, manufactured by Mikasa Co., Ltd.), and dried by heating at 100° C. for 3 minutes using a hot plate (SCW-636, manufactured by Dainippon Screen Mfg. Co., Ltd.) to form a 10 μm coating film. This copper substrate having the coating film formed thereon was exposed at 200 mJ/cm² with an ultrahigh-pressure mercury lamp as a light source, via a photomask having a 100 μm×100 μm square pattern, using an aligner (PLA-501F, manufactured by Canon Inc.). The illuminance at 365 nm was measured and used to calculate the amount of exposure. Then, the coating film was heated at 120° C. for 1 minute, developed with 2 paddles for 45 seconds using an aqueous solution of 2.38 mass % tetramethylammonium hydroxide (TMA1) as a developing solution, and using an automatic developing machine (AD-1200, manufactured by Takizawa Sangyo K. K), and rinsed with pure water for 30 seconds. Then, the resulting product was heated to 280° C. at a heating rate of 3.5° C./minute at an oxygen concentration of 20 ppm or less, using an inert oven (CLH-21CD-S, manufactured by Koyo Thermo Systems Co., Ltd), and then heated for 1 hour. The shear strength of the pattern of the resulting cured film was measured using a die shear tester (Dage-series 4000, manufactured by Nordson Corporation) under conditions including a 150 μm wide tool, a height of 1 μm from the copper substrate, and a rate of 15 μm/second. The average of 10 measured values was regarded as a shear strength. The substrate adhesion was evaluated on the basis of the below-described criteria. A and B were rated pass, and C was rated fail.
A: the shear strength was 300 mN or more.
B: the shear strength was 250 mN or more and less than 300 mN.
C: the shear strength was less than 250 mN.
   (6) Evaluation of substrate adhesion of positive type resin composition containing (D-1) photoacid generator

A positive resin composition containing (D-1) the photoacid generator was applied to a copper substrate using a. spin coater (11H-360S, manufactured by Mikasa Co., Ltd.), and dried by heating at 100° C. for 3 minutes using a hot plate (SCW-636, manufactured by Dainippon Screen Mfg. Co., Ltd.) to form a 10 μm coating film. This copper substrate having the coating film formed thereon was exposed at 800 mJ/cm² with an ultrahigh-pressure mercury lamp as a light source, via a photomask having a 100 μm×100 μm square pattern, using an aligner (PLA-501F, manufactured by Canon Inc.). The illuminance at 365 nm was measured and used to calculate the amount of exposure. Then, the coating film was developed with 2 paddles for 45 seconds using an aqueous solution of 2.38 mass % tetramethylammonium hydroxide (TMAH) as a developing solution, and using an automatic developing machine (AD-1200, manufactured by Takizawa Sangyo K.K.), and rinsed with pure water for 30 seconds. Then, the resulting product was heated to 280° C. at a heating rate of 3.5° C./minute at an oxygen concentration of 20 ppm or less, using an inert oven (CLH-21 CD-S, manufactured by Koyo Thermo Systems Co., Ltd.), and then heated for 1 hour. The shear strength of the pattern of the resulting cured film was measured using a die shear tester (Dage-series 4000, manufactured by Nordson Corporation) under conditions including a 150 μm wide tool, a height of 1 μm from the copper substrate, and a rate of 15 μm/second. The average of 10 measured values was regarded as a shear strength. The substrate adhesion was evaluated on the basis of the below-described criteria. A and B were rated pass, and C was rated fail.
A: the shear strength was 300 mN or more.
B: the shear strength was 250 mN or more and less than 300 mN.
C: the shear strength was less than 250 mN.
   (7) Evaluation of substrate adhesion of negative type resin composition containing (D-1) photoacid generator

A negative type resin composition containing (D-1) the photoacid generator was applied to a copper substrate using a spin coater (1H-360S, manufactured by Mikasa Co., Ltd), and dried by heating at 120° C. for 3 minutes using a hot plate (SCW-636, manufactured by Dainippon Screen Mfg. Co., Ltd.) to form a 15 μm coating film. This copper substrate having the coating film formed thereon was exposed at 500 mJ/cm² with an ultrahigh-pressure mercury lamp as a light source, via a photomask having a 100 μm×100 μm square pattern, using an aligner (PLA-501F, manufactured by Canon Inc.). The illuminance at 365 nm was measured and used to calculate the amount of exposure. Then, the coating film was heated at 100° C. for 1 minute, developed with 2 paddles for 30 seconds using an aqueous solution of 2,38 mass % tetramethylammonium hydroxide (TMAH) as a developing solution, and using an automatic developing machine (AD-1200, manufactured by Takizawa Sangyo K.K.), and rinsed with pure water for 30 seconds. Then, the resulting product was heated to 200° C. at a heating rate of 3.5° C./minute at an oxygen concentration of 20 ppm or less, using an inert oven (CLH-21CD-S, manufactured by Koyo Thermo Systems Co., Ltd), and then heated for I hour. The shear strength of the pattern of the resulting cured film was measured using a die shear tester (Dage-series 4000, manufactured by Nordson Corporation) under conditions including a 150 μm wide tool, a height of 1 μm from the copper substrate, and a rate of 15 μm/second. The average of 10 measured values was regarded as a shear strength. The substrate adhesion was evaluated on the basis of the below-described criteria. A and B were rated pass, and C was rated fail.
A: the shear strength was 200 mN or more.
B: the shear strength was 150 mN or more and less than 200 mN.
C: the shear strength was less than 150 mN.
   (8) Evaluation of storage stability

When 12 to 24 hours elapsed after a resin composition was prepared, its viscosity was measured at 25° C. using an E type viscometer (TVE-25, manufactured by Toki Sangyo Co., Ltd). The value measured was denominated as V₁. Then. the resin composition was hermetically enclosed, and stored at room temperature (23° C.) for 4 weeks. Then, its viscosity was measured, and the value measured was denominated as V₂. Assuming that the viscosity increase ratio (%) is (V₂-V₁)/V₁×100, the storage stability was evaluated on the basis of the below-described criteria. A, B. and C were rated pass, and D was rated fail.
A: the viscosity increase ratio was less than 3%.
B: the viscosity increase ratio was 3% or more and less than 5%.
C: the viscosity increase ratio was 5° % or more and less than 200%.
D: the viscosity increase ratio was 20% or more.

### Synthesis Example 1: Synthesis of Polyhydroxystyrene (P2)

To a solution mixture of 500 ml of tetrahydrofuran with 0.01 mol of see-butyl lithium added thereto as an initiator, p-t-butoxy styrene and styrene at a molar ratio of 3:1 were added in a total amount of 20 g. The resulting mixture was allowed to polymerize with stirring at 120° C. for 3 hours. A polymerization termination reaction was performed by adding 0. 1 mol of methanol to the reaction solution. Next, to purify the polymer, the reaction mixture was poured into methanol, and the polymer sedimented was dried to obtain a white polymer. Furthermore, the polymer was dissolved in 400 mL of acetone. A small amount of concentrated hydrochloric acid was added at 60° C. The resulting mixture was stirred for 7 hours, and then poured into water to allow the polymer to sediment. Thus, the p-t-butoxystyrene was deprotected, and converted into hydroxystyrene, which was washed and dried to obtain a copolymer (P1) of purified p-hydroxystyrene and styrene.

### Synthesis Example 2: Synthesis of Polyimide Precursor (P2)

Under a dry nitrogen gas stream, 4,4′-oxydiphthalic anhydride (hereinafter referred to as ODPA) (21.72 g, 0.070 mol) and γ-butyrolactone (hereinafter referred to as GBL) were dissolved in GBL in a flask. Subsequently, 3-aminophenol (hereinafter referred to as MAP) (1.53 g, 0 014 mol), 1,3-bis(3-aminopropyl)tetramethyl disiloxane (hereinafter referred to as SiDA) (0.87 g, 0.00035 mol), and 2,2-his(3-aminophenyl)hexafluoropropane (19.72 g, 0.059 mot) were added, and the resulting mixture was stirred at 60° C. for 4 hours. The reaction solution was left to cool, and then poured into 2.5 L of water to generate a white precipitate, which was filtrated, washed with water three times, and then dried in vacuo at 80° C. for 24 hours to obtain a polyimide precursor (P21).

### Synthesis Example 3: Synthesis of Polyimide Precursor (P3)

A polyimide precursor (P3) was obtained in the same manner as in Synthesis Example 2 except that 2,2-bis(3-aminophenyl)hexafluoropropane (19.72 g, 0.059 mol) was changed to 2,2-bis(3-amino-4-t-hydroxyphenyl)hexafluoropropane (hereinafter referred to as BAHF) (21.55 g, 0.059 mol).

### Synthesis Example 4: Synthesis of Polyimide (P4)

The reaction solution obtained in Synthesis Example 3 was further heated to 200° C., and stirred for 4 hours. The reaction solution was left to cool, and then poured into 2.5 L of water to generate a white precipitate, which was filtrated, washed with water three times, and then dried in vacuo at 80° C. for 24 hours to obtain a polyimide (P4).

### Synthesis Example 5: Synthesis of Polyimide (P5)

Under a dry nitrogen gas stream, 4-(2,5-dioxotetrahydrofuran-3-yl)-1,2,3,4-tetrahydronaphthalene-1,2-dicarboxylic dianhydride (hereinafter referred to as TDA-100) (30.03 g, 0.1 mol) was add to 100 g of GBL, and dissolved with stirring at 60° C. Subsequently, MAP (0.55 g, 0.005 mol) and 2-bis(3-aminophenyl)hexafluoropropane (30. 1 g, 0.09 mol) were added. The resulting mixture was stirred at 60° C. for 1 hour, subsequently heated to 200° C., and stirred for 4 hours. Subsequently, the reaction solution was left to cool, and poured into 3 L of water to generate a precipitate. This precipitate was collected by filtration, washed with water three times, and then dried with a vacuum dryer at 80° C. for 5 hours to obtain a polyimide (P5).

### Synthesis Example 6: Synthesis of Polyimide (P6)

A polyimide (P6) was obtained in the same manner as in Synthesis Example 5 2′5 except that 2,2-bis(3-aminophenyl)hexafluoropropane (30.08 g, 0.09 mol) was changed to BAHF (32.96 g, 0.09 mol). [Synthesis Example 7: Synthesis of Polyimide Precursor (P)7)]Under a dry nitrogen gas stream, ODPA (31 02 g, 0.10 mol) was dissolved in 200 g of GBL. To the resulting solution, BAHF (32.96 g, 0.09 mol: 90 mol % with respect to all of the amines and the derivatives thereof) was added. The resulting mixture was stirred at 20° C. for 1 hour, and subsequently stirred at 50° C. for 2 hours. Subsequently, MAP (1.09 g, 0.01 mol: 10 mol % with respect to all of the amines and the derivatives thereof) was added. The resulting mixture was stirred at 50° C. for 2 hours. Then, a solution of N,N-dimethyl formamide dimethyl acetal (21.5 g, 0.18 mol) diluted in 20 g of GBL was added in small installments. The resulting mixture was further stirred at 50° C. for 3 hours. Subsequently, the reaction solution was left to cool, and poured into 3 L of water to generate a precipitate. This precipitate was collected by filtration, washed with water three times, and then dried with a vacuum dryer at 80° C. for 5 hours to obtain a polyimide precursor (P7).

### Synthesis Example 8: Synthesis of Polybenzoxazole Precursor (P8)

Under a dry nitrogen gas stream, 1,1′-(4,4′-oxybenzoyl)dimidazole (hereinafter referred to as PBOM) (22.93 g, 0.100 mol) was dissolved in 234.67 g of NMP at 60° C. To the resulting solution, MAP (1.09 g, 0.010 mol) together with 5 g of NMP was added. The resulting mixture was allowed to react at 85° C. for 15 minutes. Then, 6FAP (32.55 g, 0.105 mol) together with 20 g of NMP was added. The resulting mixture was allowed to react at 85° C. for 3 hours. After completion of the reaction, the reaction solution was cooled to room temperature, and poured into 3 L of water to obtain a white precipitate. This precipitate was collected by filtration, washed with water three times, and then dried with a forced-air dryer at 50° C. for 3 days to obtain a powdery polybenzoxazole precursor (P8).

### Synthesis Example 9: Synthesis of Polybenzoxazole (P9)

The reaction solution obtained in Synthesis Example 8 was further heated to 200° C., and stirred for 4 hours. The reaction solution was left to cool, and then poured into 2.5 L of water to generate a white precipitate, which was filtrated, washed with water three times, and then dried in vacuo at 80° C. for 24 hours to obtain a polybenzoxazole (P9).

### Synthesis Example 10: Synthesis of Organic Salt (M1)

Under a dig nitrogen gas stream, ODPA (6.20 g, 0.020 mol) and 200 g of ion-exchanged water were added to a flask, and the resulting mixture was stirred at 80° C. to hydrolyze ODPA. Subsequently, 2,2-bis(3-aminophenyl)hexafluoropropane (6.68 g, 0.020 mol) was added. The resulting mixture was stirred at 80° C. for 1 hour. The resulting yellowish-white precipitate was filtrated, washed with water three times, and then dried in vacuo at 80° C. for 24 hours to obtain an organic salt (Mt).

### Synthesis Example 11: Synthesis of Organic Salt (M2)

An organic salt (M2) was obtained in the same manner as in Synthesis Example 10 except that 2,2-bis(3-aminophenyl)hexafluoropropane (6.68 g, 0.020 mol) was changed to BAHF (7.33 g, 0.020 mol).

The names of the compounds used in Examples and Comparative Examples are shown below.

### Synthesis Example 12: Synthesis of Organic Salt (M3)

An organic salt (M3) was obtained in the same manner as in Synthesis Example 10 except that 2,2-bis(3-aminophenyl)hexafluoropropane (6.68 g, 0.020 mol) was changed to 2,2-bis(3-amino-4-hydroxyphenyl)propane (5.17 g, 0.020 mol).

### Synthesis Example 13: Synthesis of Organic Salt (M4)

An organic salt (M4) was obtained in the same manner as in Synthesis Example 10 except that ODPA (6.20 g, 0.02 mol) was changed to TDA-100 (6.01 g, 2′5 0.02 mol).

### Synthesis Example 14: Synthesis of Organic Salt (M5)

An organic salt (M5) was obtained in the same manner as in Synthesis Example 11 except that ODPA (6.20 g, 0.02 mol) was changed TDA-100 (6.01 g, 0.02 mol).

### Synthesis Example 15: Synthesis of Organic Salt (M6)

An organic salt (M6) was obtained in the same manner as in Synthesis Example 12 except that ODPA (6.20 g, 0.02 mol) was changed TDA-100 (6.01 g, 0.02 mol).

### Synthesis Example 16: Synthesis of Organic Salt (M7)

An organic salt (M7) was obtained in the same manner as in Synthesis Example 10 except that ODPA (6.20 g, 0.02 mol) was changed to 4,4′-dicarboxydiphenyl ether (5.16 g, 0.02 mol).

### Synthesis Example 1 7: Synthesis of Organic Salt (M8)

An organic salt (M8) was obtained in the same manner as in Synthesis Example 11 except that ODPA (6.20 g, 0.02 mol) was changed to 4,4′-dicarboxydiphenyl ether (5,16 g, 0.02 mol).

### Synthesis Example 18: Synthesis of Organic Salt (M9)

An organic salt (M97) was obtained in the same manner as in Synthesis Example 12 except that ODPA (6.20 g, 0.02 mob) was changed to 4,4′-dicarboxydiphenyl ether (5.16 g, 0.02 mol).

### Synthesis Example 19: Synthesis of Organic Salt (M10)

An organic salt (M10) was obtained in the same manner as in Synthesis Example 10 except that ODPA (6.20 g, 0.020 mol) was changed to phthalic anhydride (2.96 g, 0.020 mol), and that 2,2-bis(3-aminophenyl)hexafluoropropane (6.68 g, 0.020 mol) was changed to aniline (1.86, 0.020 mol).

The names of the compounds used in Examples and Comparative Examples are show % n below.

### <(C) Solvent>

GBL: γ-butyrolactone
EL: Ethyl lactate

### <(D-1) Photoacid Generator>

HA5-170: HA5-170 (manufactured by Toyo Gosei Co., Ltd.)
CPI-310FG: CPI-31OFG (manufactured by San-Apro Ltd.)

### <(D-2) Photoinitiator>

OXE02: “Irgacure” (registered trademark) OXE02 (manufactured by BASF Japan Ltd,)

### <Radical Polymerizable Compound>

DCP-A: LIGHT ACRYLATE DCP-A (mannufactured by Kvoeisha Chemical Co., Ltd.)
BP-6E.M: LIGHT ESTER BP-6EM (manufacured by Kyoeisha Chemical Co., Ltd.)
MOI-BP: Karenz MOI-BP (manufactured by Showa Denko K.K.)

### <Crosslinking Agent>

MW-IOOLM: “NhIKALAC” (registered trademark) MW-100LM (manufactured by Sanwa Chemical Co., Ltd.)
MX-270: “NIKALAC” (registered trademark) MX-270 (manufactured by Sanwa Chemical Co., Ltd.)
TEPIC-VL: TEPIC-VL (manufactured by Nissan Chemical Corporation)

### <Adhesion Improve Reagent>

KBM403 (manufactured by Shin-Etsu Chemical Co., Lid.)

### <Surfactant>

PF77: POLYFLOW No. 77 (manufactured by Kyoeisha Chemical Co., Ltd. )

### Example I

The polyhydroxystyrene (P1) in an amount of 3.5 g, 0.0175 g of the organic salt (M1), 2.1 g of GBL, and 3.1 g of EL were mixed. The resulting mixture was filtrated under pressure through a filter for trapping particles having a diameter of 1 μm to prepare a non-photosensitive resin composition. In accordance with the evaluation methods in (4) and (8) above, the substrate adhesion and storage stability of the non-photosensitive resin composition were evaluated.

### Examples 2 to 19

Using (A) the soluble resin, (B) the organic salt, and (C) the solvent as shown in Table 1, a non-photosensitive resin composition was prepared in the same manner as in Example 1. The substrate adhesion and storage stability of the non-photosensitive resin composition were evaluated in accordance with the evaluation methods in (4) and (8) above.

### Comparative Examples 1 to 5

Using (A) the soluble resin, (B) the organic salt, and (C) the solvent as shown in Table 1, a non-photosensitive resin composition was prepared in the same manner as in Example 1. The substrate adhesion and storage stability of the non-photosensitive resin composition were evaluated in accordance with the evaluation methods in (4) and (8) above.

TABLE 1

| | | | | Amount of (B) |
|---|---|---|---|---|
| | | | | Organic Salt with |
| | | | | respect to 100 Parts |
| | (A) | (B) | | by Mass of (A) |
| | Soluble | Organic | (C) | Soluble Resin (Parts |
| | Resin | Salt | Solvent | by Mass) |
| Example 1 | P1 | M1 | GBL(2.1) | 0.5 |
| | (3.5) | (0.0175) | EL(2.6) | |
| Example 2 | P2 | M1 | GBL(2.1) | 0.5 |
| | (3.5) | (0.0175) | EL(2.6) | |
| Example 3 | P3 | M1 | GBL(2.1) | 0.5 |
| | (3.5) | (0.0175) | EL(2.6) | |
| Example 4 | P4 | M1 | GBL(2.1) | 0.5 |
| | (3.5) | (0.0175) | EL(2.6) | |
| Example 5 | P4 | M2 | GBL(2.1) | 0.5 |
| | (3.5) | (0.0175) | EL(2.6) | |
| Example 6 | P4 | M2 | GBL(2.1) | 1 |
| | (3.5) | (0.035) | EL(2.6) | |
| Example 7 | P4 | M2 | GBL(2.1) | 0.05 |
| | (3.5) | (0.00175) | EL(2.6) | |
| Example 8 | P4 | M2 | GBL(2.1) | 5 |
| | (3.5) | (0.175) | EL(2.6) | |
| Example 9 | P4 | M2 | GBL(2.1) | 10 |
| | (3.5) | (0.35) | EL(2.6) | |
| Example 10 | P4 | M2 | GBL(2.1) | 0.01 |
| | (17.5) | (0.00175) | EL(2.6) | |
| Example 11 | P4 | M3 | GBL(2.1) | 0.5 |
| | (3.5) | (0.0175) | EL(2.6) | |
| Example 12 | P7 | M2 | GBL(2.1) | 0.5 |
| | (3.5) | (0.0175) | EL(2.6) | |
| Example 13 | P4 | M8 | GBL(2.1) | 0.5 |
| | (3.5) | (0.0175) | EL(2.6) | |
| Example 14 | P8 | M7 | GBL(2.1) | 0.5 |
| | (3.5) | (0.0175) | EL(2.6) | |
| Example 15 | P8 | M8 | GBL(2.1) | 0.5 |
| | (3.5) | (0.0175) | EL(2.6) | |
| Example 16 | P9 | M8 | GBL(2.1) | 0.5 |
| | (3.5) | (0.0175) | EL(2.6) | |
| Example 17 | P9 | M9 | GBL(2.1) | 0.5 |
| | (3.5) | (0.0175) | EL(2.6) | |
| Example 18 | P9 | M2 | GBL(2.1) | 0.5 |
| | (3.5) | (0.0175) | EL(2.6) | |
| Example 19 | P1 | M10 | GBL(2.1) | 0.5 |
| | (3.5) | (0.0175) | EL(2.6) | |
| Comparative | P1 | — | GBL(2.1) | 0 |
| Example 1 | (3.5) | | EL(2.6) | |
| Comparative | P1 | M1 | GBL(2.1) | 12 |
| Example 2 | (3.5) | (0.042) | EL(2.6) | |
| Comparative | P1 | M1 | GBL(2.1) | 0.005 |
| Example 3 | (3.5) | (0.000875) | EL(2.6) | |
| Comparative | P1 | M7 | GBL(2.1) | 12 |
| Example 4 | (3.5) | (0.042) | EL(2.6) | |
| Comparative | P1 | M7 | GBL(2.1) | 0.005 |
| Example 5 | (3.5) | (0.000875) | EL(2.6) | |

^{Note)}
in the table, numeral values in parenthesis represent added amounts [unit: g].

The evaluation results in Example 1 to Example 19 and Comparative

### Example 1 to Comparative Example 5 are shown in Table 2

TABLE 2

| | Substrate Adhesion | | | Strage | | |
|---|---|---|---|---|---|---|
| | Number of the Squares of | | | Stability | | |
| | the Cured Film that were | | | Viscosity | | |
| | adhering to the Substrate | Eval- | | Increase | Eval- | |
| | After the Test (pieces) | uation | | Ratio (%) | uation | |
| Example 1 | 92 | B | pass | 4 | B | pass |
| Example 2 | 100 | A | pass | 8 | C | pass |
| Example 3 | 100 | A | pass | 8 | C | pass |
| Example 4 | 100 | A | pass | 3 | B | pass |
| Example 5 | 100 | A | pass | 4 | B | pass |
| Example 6 | 100 | A | pass | 6 | C | pass |
| Example 7 | 95 | B | pass | 2 | A | pass |
| Example 8 | 100 | A | pass | 10 | C | pass |
| Example 9 | 100 | A | pass | 16 | C | pass |
| Example 10 | 88 | B | pass | 1 | A | pass |
| Example 11 | 100 | A | pass | 4 | B | pass |
| Example 12 | 100 | A | pass | 6 | C | pass |
| Example 13 | 100 | A | pass | 4 | B | pass |
| Example 14 | 100 | A | pass | 8 | C | pass |
| Example 15 | 100 | A | pass | 3 | B | pass |
| Example 16 | 100 | A | pass | 4 | B | pass |
| Example 17 | 100 | A | pass | 3 | B | pass |
| Example 18 | 100 | A | pass | 4 | B | pass |
| Example 19 | 85 | B | pass | 4 | B | pass |
| Comparative | 30 | D | fail | 0 | A | pass |
| Example 1 | | | | | | |
| Comparative | 98 | B | pass | 25 | D | fail |
| Example 2 | | | | | | |
| Comparative | 55 | C | fail | 0 | A | pass |
| Example 3 | | | | | | |
| Comparative | 95 | B | pass | 24 | D | fail |
| Example 4 | | | | | | |
| Comparative | 40 | C | fail | 1 | A | pass |
| Example 5 | | | | | | |

### Example 20

Under yellow light, 1˜5 g of the polyhydroxystyrene (P1). 0.0175 g of the organic salt (M-1), 0.5 g of OXE02, 0.5 g of DCP-A, 1.5 g of BP-6EM, 0.5 of MOI-BP, 1.0 g of MW-100LM, 0.5 g of MX-270, 0.2.5 g of KBM403, 0.003 g of PF77, 2.1 g of GBL, and 3.1 2 of EL were mixed. The resulting mixture was filtrated under pressure through a filter for trapping particles having, a diameter of 1 μm to prepare a negative type resin composition. In accordance with the evaluation methods in (1), (5), and (8) above, the fine pattern processability, substrate adhesion, and storage stability of the negative type resin composition containing (D-2) the photoinitiator were evaluated.

### [Example 21] to [Example 40]

Using (A) the soluble resin, (B) the organic salt, (C) the solvent, (D) the photosensitizer, and other components as shown in Table 3-1 and Table 3-2, a negative type resin composition containing (D-2) the photoinitiator was prepared in the same manner as in Example 20. In accordance with the evaluation methods in (1), (5), and (8) above, the fine pattern processability, substrate adhesion, and storage stability of the negative type resin composition containing (D-2) the photoinitiator were evaluated.

### [Comparative Example 6] to [Comparative Example 10]

Using (A) the soluble resin, (B) the organic salt, (C) the solvent, (D) the photosensitizer, and other components as shown in Table 3-2, a negative type resin composition containing (D-2) the photoinitiator was prepared in the same manner as in Example 20. In accordance with the evaluation methods in (1), (5), and (8) above, the fine pattern processability, substrate adhesion, and storage stability of the negative type resin composition containing (D-2) the photoinitiator were evaluated.

TABLE 3-1

| | | | | (D-2) | | | | | Amount of (B) Organic |
|---|---|---|---|---|---|---|---|---|---|
| | (A) | (B) | | Photopoly- | Poly- | Cross | Adhesive- | | Salt with respect to 100 |
| | Soluble | Organic | (C) | merization | merizable | Linking | ness | | Parts by Mass of (A) |
| | Resin | Salt | Solvent | Initiator | Monomer | Agent | Improver | Surfactant | Soluble Resin (Parts by Mass) |
| Example 20 | P1 | M1 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 21 | P2 | M1 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 22 | P3 | M1 | GBL(2.1) | OXE02 | DCP-A(0 5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 23 | P4 | M1 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 24 | P4 | M2 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 25 | P4 | M2 | GBL(2.1) | OXE02 | DCP-A(0.5) | MW-100LM(0.5) | KBM403 | PF77 | 1 |
| | (3.5) | (0.035) | EL(3.1) | (0.5) | BP-6EM(1.5) | MX-270(0.5) | (0.25) | (0.003) | |
| | | | | | MOI-BP(0.5) | | | | |
| Example 26 | P4 | M2 | GBL(2.1) | OXE02 | DCP-A(0.5) | MW-100LM(0.5) | KBM403 | PF77 | 0.05 |
| | (3.5) | (0.00175) | EL(3.1) | (0.5) | BP-6EM(1.5) | MX-270(0.5) | (0.25) | (0.003) | |
| | | | | | MOI-BP(0.5) | | | | |
| Example 27 | P4 | M2 | GBL(2.1) | OXE02 | DCP-A(0.5) | MW-100LM(0.5) | KBM403 | PF77 | 5 |
| | (3.5) | (0.175) | EL(3.1) | (0.5) | BP-6EM (1.5) | MX-270(0.5) | (0.25) | (0.003) | |
| | | | | | MOI-BP(0.5) | | | | |
| Example 28 | P4 | M2 | GBL(2.1) | OXE02 | DCP-A(0.5) | MW-100LM(0.5) | KBM403 | PF77 | 10 |
| | (3.5) | (0.35) | EL(3.1) | (2.5) | BP-6EM(1.5) | MX-270(0.5) | (0.25) | (0.003) | |
| | | | | | MOI-BP(0.5) | | | | |
| Example 29 | P4 | M2 | GBL(10.5) | OXE02 | DCP-A(2.5) | MW-100LM(2.5) | KBM403 | PF77 | 0.01 |
| | (17.5) | (0.00175) | EL(15.5) | (2.5) | BP-6EM (7.5) | MX-270(2.5) | (1.25) | (0.015) | |
| | | | | | MOI-BP(2.5) | | | | |
| Example 30 | P4 | M3 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 31 | P7 | M2 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 32 | P4 | M8 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |

^{Note)}
In the table, numeral values in parenthesis represent added amounts [unit: g].

TABLE 3-2

| | | | | | | | | | Amount of (B) Organic |
|---|---|---|---|---|---|---|---|---|---|
| | | | | (D-2) | | | | | Salt with respect to 100 |
| | (A) | (B) | | Photopoly- | | Cross | | | Parts by Mass of (A) |
| | Soluble | Organic | (C) | merization | Polymerizable | Linking | Adhesiveness | | Soluble Resin |
| | Resin | Salt | Solvent | Initiator | Monomer | Agent | Improver | Surfactant | (Parts by Mass) |
| Example 33 | P8 | M7 | GBL(2 1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 34 | P8 | M8 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 35 | P8 | M9 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 36 | P9 | M7 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 37 | P9 | M8 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 38 | P9 | M9 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 39 | P9 | M2 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Example 40 | P1 | M10 | GBL(2.1) | OXE02 | DCP-A(0.5) | MW-100LM(0.5) | KBM403 | PF77 | 0.5 |
| | (3.5) | (0.0175) | EL(3.1) | (0.5) | BP-6EM(1.5) | MX-270(0.5) | (0.25) | (0.003) | |
| | | | | | MOI-BP(0.5) | | | | |
| Comparative | P1 | — | GBL(2.1) | OXE02 | DCP-A(0.5) | MW-100LM(0.5) | KBM403 | PF77 | 0 |
| Example 6 | (3.5) | | EL(3.1) | (0.5) | BP-6EM(1.5) | MX-270(0.5) | (0.25) | (0.003) | |
| | | | | | MOI-BP(0.5) | | | | |
| Comparative | P1 | M1 | GBL(2.1) | OXE02 | DCP-A(0.5) | MW-100LM(0.5) | KBM403 | PF77 | 12 |
| Example 7 | (3.5) | (0.42) | EL(3.1) | (0.5) | BP-6EM(1.5) | MX-270(0.5) | (0.25) | (0.003) | |
| | | | | | MOI-BP(0 5) | | | | |
| Comparative | P1 | M1 | GBL(10.5) | OXE02 | DCP-A(2.5) | MW-100LM(2.5) | KBM403 | PF77 | 0.005 |
| Example 8 | (17.5) | (0.000875) | EL(15.5) | (2.5) | BP-6EM(7.5) | MX-270(2.5) | (1.25) | (0.015) | |
| | | | | | MOI-BP(2.5) | | | | |
| Comparative | P1 | M7 | GBL(2.1) | OXE02 | DCP-A(0.5) | MW-100LM(0.5) | KBM403 | PF77 | 12 |
| Example 9 | (3.5) | (0.42) | EL(3.1) | (0.5) | BP-SEM(1.5) | MX-270(0.5) | (0.25) | (0.003) | |
| | | | | | MOI-BP(0.5) | | | | |
| Comparative | P1 | M7 | GBL(10.5) | OXE02 | DCP-A(2.5) | MW-100L.M(2.5) | KBM403 | PF77 | 0.005 |
| Example 10 | (17.5) | (0.000875) | EL(15.5) | (2.5) | BP-SEM(7.5) | MX-270(2.5) | (1.25) | (0.015) | |
| | | | | | MOI-BP(2.5) | | | | |

^{Note)}
In the table, numeral values in parenthesis represent added amounts [unit: g].

The evaluation results in Examples 20 to 40 and Comparative. Examples 6 to 10 are shown in Table 4.

TABLE 4

| | (1) Fine Pattern Procesability | | | (2) Substrate Adhesion | | | (3) Storage Stability | | |
|---|---|---|---|---|---|---|---|---|---|
| | The Smallest | | | Shear | | | Viscosity | | |
| | Pattern Size | | | Strength | | | Increase | | |
| | (μm) | Evaluation | | (mN) | Evaluation | | Ratio (%) | Evaluation | |
| Example 20 | 30 μm | C | pass | 266 | B | pass | 4 | B | pass |
| Example 21 | 30 μm | C | pass | 300 | A | pass | 10 | C | pass |
| Example 22 | 20 μm | B | pass | 310 | A | pass | 0 | C | pass |
| Example 23 | 20 μm | B | pass | 314 | A | pass | 4 | B | pass |
| Example 24 | 15 μm | A | pass | 325 | A | pass | 4 | B | pass |
| Example 25 | 15 μm | A | pass | 350 | A | pass | 7 | C | pass |
| Example 26 | 20 μm | B | pass | 270 | B | pass | 3 | B | pass |
| Example 27 | 15 μm | A | pass | 370 | A | pass | 9 | C | pass |
| Example 28 | 20 μm | B | pass | 400 | A | pass | 15 | C | pass |
| Example 29 | 20 μm | B | pass | 260 | B | pass | 2 | A | pass |
| Example 30 | 20 μm | B | pass | 310 | A | pass | 4 | B | pass |
| Example 31 | 15 μm | A | pass | 320 | A | pass | 5 | C | pass |
| Example 32 | 15 μm | A | pass | 325 | A | pass | 0 | B | pass |
| Example 33 | 20 μm | B | pass | 305 | A | pass | 6 | C | pass |
| Example 34 | 15 μm | A | pass | 305 | A | pass | 5 | C | pass |
| Example 35 | 20 μm | B | pass | 325 | A | pass | 5 | C | pass |
| Example 36 | 20 μm | B | pass | 315 | A | pass | 4 | B | pass |
| Example 37 | 15 μm | A | pass | 310 | A | pass | 4 | B | pass |
| Example 38 | 20 μm | B | pass | 330 | A | pass | 4 | B | pass |
| Example 39 | 15 μm | A | pass | 310 | A | pass | 4 | B | pass |
| Example 40 | 30 μm | C | pass | 255 | B | pass | 0 | B | pass |
| Comparative | 30 μm | C | pass | 224 | C | fail | 0 | A | pass |
| Example 6 | | | | | | | | | |
| Comparative | 30 μm was | D | fail | 408 | A | pass | 22 | D | fail |
| Example 7 | not achieved | | | | | | | | |
| | by processing | | | | | | | | |
| Comparative | 30 μm | C | pass | 230 | C | fail | 1 | A | pass |
| Example 8 | | | | | | | | | |
| Comparative | 30 μm was | D | fail | 400 | A | pass | 25 | D | fail |
| Example 9 | not achieved | | | | | | | | |
| | by processing | | | | | | | | |
| Comparative | 30 μm | C | pass | 240 | C | fail | 0 | A | pass |
| Example 10 | | | | | | | | | |

### Example 411

Under yellow light, 3.5 g of the polyhydroxystyrene (1P1), 0.0175 g of the organic salt (M1), 0.4 g of HA5-170, 0.17 g of TrisP-PA, 0.34 g of MX-270, 0.33 g of KBM1403, 4.3 g of GBL, and 2.4 g of EL were mixed. The resulting mixture was filtrated under pressure through a filter for trapping particles having a diameter of 1 μm to prepare a positive type resin composition containing (D-1) the photoacid generator. In accordance with the evaluation methods in (2), (6), and (8) above, the fine pattern processability, substrate adhesion, and storage stability of the positive type resin composition containing (D-1) the photoacid generator were evaluated

### Examples 42 to 611

Using (A) the soluble resin, (B) the organic salt, (C) the solvent, (D) the photosensitizer, and other components as shown in Table 5-1 and Table 5-2, a positive type resin composition containing (D-1) the photoacid generator was prepared in the same manner as in Example 41. In accordance with the evaluation methods in (2), (6), and (8) above, the fine pattern processability substrate adhesion, and storage stability of the positive type resin composition containing (D-1) the photoacid generator were evaluated.

### Comparative Examples 11 to 15

Using (A) the soluble resin, (B) the organic salt, (C) the solvent, (D) the photosensitizer, and other components as shown in Table 5-2, a positive type resin composition containing (D-1) the photoacid generator was prepared in the same manner as in Example 41. In accordance with the evaluation methods in (2), (6), and (8) above, the fine pattern processability, substrate adhesion, and storage stability of the positive type resin composition containing ((D-1) the photoacid generator were evaluated.

TABLE 5-1

| | | | | | | | | Amount of (B) Organic |
|---|---|---|---|---|---|---|---|---|
| | | | | | | | | Salt with respect to |
| | (A) | (B) | | (D-1) Photo | Cross | | | 100 Parts by Mass of |
| | Soluble | Organic | (C) | Acid | Linking | Solubility | Adhesiveness | (A) Soluble Resin |
| | Resin | Salt | Solvent | Generator | Agent | Promotor | Improver | (Parts by Mass) |
| Example 41 | P1 | M1 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 42 | P2 | M1 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 43 | P3 | M1 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 44 | P4 | M1 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 45 | P4 | M2 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 46 | P4 | M2 | GBL(4.3) | HA5-170 | MX-270 | TrisP-PA | KBM1403 | 1 |
| | (3.5) | (0.035) | EL(2.4) | (0.4) | (0.34) | (0.17) | (0.33) | |
| Example 47 | P4 | M2 | GBL(4.3) | HA5-170 | MX-270 | TrisP-PA | KBM1403 | 0.05 |
| | (3.5) | (0.00175) | EL(2.4) | (0.4) | (0.34) | (0.17) | (0.33) | |
| Example 48 | P4 | M2 | GBL(4.3) | HA5-170 | MX-270 | TrisP-PA | KBM1403 | 5 |
| | (3.5) | (0.175) | EL(2.4) | (0.4) | (0.34) | (0.17) | (0.33) | |
| Example 49 | P4 | M2 | GBL(4.3) | HA5-170 | MX-270 | TrisP-PA | KBM1403 | 10 |
| | (3.5) | (0.35) | EL(2.4) | (0.4) | (0.34) | (0.17) | (0.33) | |
| Example 50 | P4 | M2 | GBL(4.3) | HA5-170 | MX-270 | TrisP-PA | KBM1403 | 0.01 |
| | (17.5) | (0.00175) | EL(2.4) | (0.4) | (0.34) | (0.17) | (0.33) | |
| Example 51 | P4 | M3 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |

^{Note)}
In the table, numeral values in parenthesis represent added amounts [unit: g].

TABLE 5-2

| | | | | | | | | Amount of (B) Organic |
|---|---|---|---|---|---|---|---|---|
| | | | | | | | | Salt with respect to |
| | (A) | (B) | | (D-1) Photo | Cross | | | 100 Parts by Mass of |
| | Soluble | Organic | (C) | Acid | Linking | Solubility | Adhesiveness | (A) Soluble Resin |
| | Resin | Salt | Solvent | Generator | Agent | Promotor | Improver | (Parts by Mass) |
| Example 53 | P7 | M2 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 53 | P4 | M8 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 54 | P8 | M7 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 55 | P8 | M8 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 56 | P8 | M9 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 57 | P9 | M7 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 58 | P9 | M8 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 59 | P9 | M9 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 60 | P9 | M2 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Example 61 | P1 | M10 | GBL(4.3) | HA5-170 | MX-270 | TrisP-PA | KBM1403 | 0.5 |
| | (3.5) | (0.0175) | EL(2.4) | (0.4) | (0.34) | (0.17) | (0.33) | |
| Comparative | P1 | — | GBL(4.3) | HA5-170 | MX-270 | TrisP-PA | KBM1403 | 0 |
| Example 11 | (3.5) | | EL(2.4) | (0.4) | (0.34) | (0.17) | (0.33) | |
| Comparative | P1 | M1 | GBL(4.3) | HA5-170 | MX-270 | TrisP-PA | KBM1403 | 12 |
| Example 12 | (3.5) | (0.42) | EL(2.4) | (0.4) | (0.34) | (0.17) | (0.33) | |
| Comparative | P1 | M1 | GBL(4.3) | HA5-170 | MX-270 | TrisP-PA | KBM1403 | 0.005 |
| Example 13 | (17.5) | (0.000875) | EL(2.4) | (0.4) | (0.34) | (0.17) | (0.33) | |
| Comparative | P1 | M7 | GBL(4.3) | HA5-170 | MX-270 | TrisP-PA | KBM1403 | 12 |
| Example 14 | (3.5) | (0.42) | EL(2.4) | (0.4) | (0.34) | (0.17) | (0.33) | |
| Comparative | P1 | M7 | GBL(4.3) | HA5-170 | MX-270 | TrisP-PA | KBM1403 | 0.005 |
| Example 15 | (17.5) | (0.000875) | EL(2.4) | (0.4) | (0.34) | (0.17) | (0.33) | |

^{Note)}
In the table, numeral values in parenthesis represent added amounts [unit: g].

The evolution results in Examples 41 to 61 and Comparative. Examples 1 to 15 are shown in Table 6.

TABLE 6

| | (1) Fine Pattern Procesability | | | (2) Substrate Adhesion | | | (3) Storage Stability | | |
|---|---|---|---|---|---|---|---|---|---|
| | The Smallest | | | Shear | | | Viscosity | | |
| | Pattern Size | | | Strength | | | Increase | | |
| | (μm) | Evaluation | | (mN) | Evaluation | | Ratio (%) | Evaluation | |
| Example 41 | 15 μm | C | fail | 254 | B | pass | 4% | B | pass |
| Example 42 | 15 μm | C | fail | 305 | A | pass | 8% | C | pass |
| Example 43 | 10 μm | B | pass | 300 | A | pass | 8% | C | pass |
| Example 44 | 10 μm | B | pass | 310 | A | pass | 4% | B | pass |
| Example 45 | 5 μm | A | pass | 313 | A | pass | 4% | B | pass |
| Example 46 | 5 μm | A | pass | 340 | A | pass | 5% | C | pass |
| Example 47 | 10 μm | B | pass | 270 | B | pass | 3% | B | pass |
| Example 48 | 5 μm | A | pass | 365 | A | pass | 8% | C | pass |
| Example 49 | 10 μm | B | pass | 380 | A | pass | 16% | C | pass |
| Example 50 | 10 μm | B | pass | 260 | B | pass | 2% | A | pass |
| Example 51 | 10 μm | B | pass | 325 | A | pass | 4% | B | pass |
| Example 52 | 5 μm | A | pass | 310 | A | pass | 6% | C | pass |
| Example 53 | 5 μm | A | pass | 313 | A | pass | 4% | B | pass |
| Example 54 | 10 μm | B | pass | 305 | A | pass | 5% | C | pass |
| Example 55 | 5 μm | A | pass | 315 | A | pass | 5% | C | pass |
| Example 56 | 10 μm | B | pass | 330 | A | pass | 6% | C | pass |
| Example 57 | 10 μm | B | pass | 305 | A | pass | 4% | B | pass |
| Example 58 | 5 μm | A | pass | 320 | A | pass | 4% | B | pass |
| Example 59 | 10 μm | B | pass | 320 | A | pass | 4% | B | pass |
| Example 60 | 5 μm | A | pass | 320 | A | pass | 4% | B | pass |
| Example 61 | 15 μm | C | pass | 250 | B | pass | 4% | B | pass |
| Comparative | 15 μm | C | pass | 230 | C | fail | 0% | A | pass |
| Example 11 | | | | | | | | | |
| Comparative | 15 μm was | D | fail | 393 | A | pass | 21% | D | fail |
| Example 12 | not achieved | | | | | | | | |
| | by processing | | | | | | | | |
| Comparative | 15 μm | C | pass | 225 | C | fail | 2% | A | pass |
| Example 13 | | | | | | | | | |
| Comparative | 15 μm was | D | fail | 400 | A | pass | 30% | D | fail |
| Example 14 | not achieved | | | | | | | | |
| | by processing | | | | | | | | |
| Comparative | 15 μm | C | pass | 240 | C | fail | 2% | A | pass |
| Example 15 | | | | | | | | | |

### Example 621

Un-der yellow light, 2.35 g of the polyhydroxystyrene (1P1), 0.0118 g of the organic salt (M1), 0.17 g of CPI-310FG, 3.0 g of TEPIC-VL, 0.20 g of KBM403, and 10 g of GBL were mixed. The resulting mixture was filtrated under pressure through a filter for trapping particles having a diameter of 1 μm to prepare a negative type resin composition containing (D-1) the photoacid generator. in accordance with the evaluation methods in (3), (7), and (8) above, the fine pattern processability, substrate adhesion, and storage stability of the negative type resin composition containing (D-1) the photoacid generator were evaluated.

### Examples 63 to 681

Using (A) the soluble resin, (B) the organic salt, (C) the solvent, (D) the photosensitizer, and other components as shown in Table 7, a negative type resin composition containing (D-1) the photoacid generator was prepared in the same manner as in Example 62. In accordance with the evaluation methods in (3), (7), and (8) above, the fine pattern processability, substrate adhesion, and storage stability of the positive type resin composition containing ((D-1) the photoacid generator were evaluated.

### Comparative Examples 16 to 18

Using (A) the soluble resin, (B) the organic salt, (C) the solvent, (D) the photosensitizer, and other components as shown in Table 7, negative type resin composition containing (D-1) the photoacid generator was prepared in the same manner as in Example 62. In accordance with the evaluation methods in (3), (7), and (8) above, the fine pattern processability, substrate adhesion, and storage stability of the positive type resin composition containing ((D-1) the photoacid generator were evaluated.

TABLE 7

| | | | | | | | Amount of (B) Organic |
|---|---|---|---|---|---|---|---|
| | | | | (D-1) | | | Salt with respect to |
| | (A) | (B) | | Photo | Cross | | 100 Parts by Mass of |
| | Soluble | Organic | (C) | Acid | Linking | Adhesiveness | (A) Soluble Resin |
| | Resin | Salt | Solvent | Generator | Agent | Improver | (Parts by Mass) |
| Example 62 | P1 | M4 | GBL(10) | CPI-310FG | TEPIC-VL | KBM403 | 0.5 |
| | (2.35) | (0.0118) | | (0.17) | (3.0) | (0.2) | |
| Example 63 | P5 | M4 | GBL(10) | CPI-310FG | TEPIC-VL | KBM403 | 0.5 |
| | (2.35) | (0.0118) | | (0.17) | (3.0) | (0.2) | |
| Example 64 | P6 | M4 | GBL(10) | CPI-310FG | TEPIC-VL | KBM403 | 0.5 |
| | (2.35) | (0.0118) | | (0.17) | (3.0) | (0.2) | |
| Example 65 | P6 | M5 | GBL(10) | CPI-310FG | TEPIC-VL | KBM403 | 0.5 |
| | (2.35) | (0.0118) | | (0.17) | (3.0) | (0.2) | |
| Example 66 | P6 | M6 | GBL(10) | CPI-310FG | TEPIC-VL | KBM403 | 0.5 |
| | (2.35) | (0.0118) | | (0.17) | (3.0) | (0.2) | |
| Example 67 | P6 | M8 | GBL(10) | CPI-310FG | TEPIC-VL | KBM403 | 0.5 |
| | (2.35) | (0.0118) | | (0.17) | (3.0) | (0.2) | |
| Example 68 | P1 | M10 | GBL(10) | CPI-310FG | TEPIC-VL | KBM403 | 0.5 |
| | (2.35) | (0.0118) | | (0.17) | (3.0) | (0.2) | |
| Comparative | P1 | — | GBL(10) | CPI-310FG | TEPIC-VL | KBM403 | 0 |
| Example 16 | (2.35) | | | (0.17) | (3.0) | (0.2) | |
| Comparative | P1 | M4 | GBL(10) | CPI-310FG | TEPIC-VL | KBM403 | 12 |
| Example 17 | (2.35) | (0.282) | | (0.17) | (3.0) | (0.2) | |
| Comparative | P1 | M4 | GBL(10) | CPI-310FG | TEPIC-VL | KBM403 | 0.005 |
| Example 18 | (2.35) | (0.00012) | | (0.17) | (3.0) | (0.2) | |

^{Note)}
In the table, numeral values in parenthesis represent added amounts [unit: g].

The evaluation results in Examples 62 to 68 and Comparative Examples 16 to 18 are shown in Table 8.

TABLE 8

| | (1) Fine Pattern Procesability | | | (2) Substrate Adhesion | | | (3) Storage Stability | | |
|---|---|---|---|---|---|---|---|---|---|
| | The Smallest | | | Shear | | | Viscosity | | |
| | Pattern Size | | | Strength | | | Increase | | |
| | (μm) | Evaluation | | (mN) | Evaluation | | Ratio (%) | Evaluation | |
| Example 62 | 15 μm | C | pass | 160 | B | pass | 4% | B | pass |
| Example 63 | 15 μm | C | pass | 220 | A | pass | 4% | B | pass |
| Example 64 | 10 μm | B | pass | 235 | A | pass | 3% | B | pass |
| Example 65 | 5 μm | A | pass | 220 | A | pass | 4% | B | pass |
| Example 66 | 10 μm | B | pass | 205 | A | pass | 4% | B | pass |
| Example 67 | 5 μm | A | pass | 220 | A | pass | 4% | B | pass |
| Example 68 | 15 μm | C | pass | 155 | B | pass | 4% | B | pass |
| Comparative | 15 μm | C | pass | 135 | C | fail | 1% | A | pass |
| Example 16 | | | | | | | | | |
| Comparative | 15 μm was | D | fail | 280 | A | pass | 24% | C | pass |
| Example 17 | not achieved | | | | | | | | |
| | by processing | | | | | | | | |
| Comparative | 15 μm | C | pass | 145 | C | fail | 2% | A | pass |
| Example 18 | | | | | | | | | |

### INDUSTRIAL APPLICABILITY

A cured product obtained by curing a resin composition according to the present invention can be used for an insulating film or a protective film that is a constituent of an electronic component, or for a planarization layer or a pixel division layer that is a constituent of a display device. Specific examples of the electronic component include: active components having a semiconductor, such as transistors, diodes, integrated circuits (ICs), and memories; and passive components such as resistors, capacitors, and inductors. More specific examples include cured products suitably used for the following applications: a. passivation film of a semiconductor; a semiconductor element; a surface protective film such as a thin film transistor (TFT) an interlayer insulating film such as an interlayer insulating film between redistributions in a 2-layer to 10-layer multilayer wiring for high density mounting; an insulating film and a protective film for a touch panel display; and an insulating layer of an organic electroluminescent device. The cured product may have any of various structures other than these. The display device is, for example, an organic EL display device having a planarization layer, 1st electrode, pixel division layer, organic EL layer, and 2nd electrode on a substrate, in which the planarization layer and/or the pixel division layer contain(s) a cured product according to the present invention. For example, an active matrix type display device includes: a substrate, such as a sheet of glass or a resin film, on which there are a TFT (thin-film transistor) and wiring that is located on a lateral portion of the TFT, and connected to the TFT; a planarization layer provided on the substrate to cover the irregular surface; and a display element further provided on the planarization layer. The display element and the wiring are connected via a contact hole formed in the planarization layer.

1. A resin composition comprising: (A) a soluble resin, (B) an organic salt, and (C) a solvent, wherein (B) the organic salt is an organic salt formed from an organic compound having a carboxy group and an organic compound having an amino group, and wherein the amount of (B) the organic salt is 0.01 to 10 parts by mass with respect to 100 parts by mass of (A) the soluble resin.

2. The resin composition according to claim 1, wherein (B) the organic salt comprises an organic salt having a structure represented by the formula (6) or the formula (7): 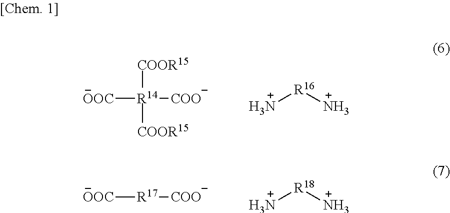
(wherein in the formula (6), R¹⁴ represents a C₄₋₄₀ tetravalent organic group; R⁵ represents a hydrogen atom or a C₁₋₁₀ monovalent organic group; and R¹⁶ represents a C₁₋₄₀ divalent organic group) and
(wherein in the formula (7), R¹⁷ represents a C₁₋₄₀ divalent organic group with the proviso that R¹⁷ contains neither a carboxy group nor a carboxylic acid ester group; and R¹⁸ represents a C₁₋₄₀ divalent organic group).

3. The resin composition according to claim 1, wherein (A) the soluble resin comprises at least one soluble resin selected from the group consisting of a polyimide, a polybenzoxazole, a precursor thereof, or a copolymer thereof.

4. The resin composition according to claim 1, further comprising (D) a photosensitizer.

5. The resin composition according to claim 1, wherein (A) the soluble resin comprises at least one soluble resin selected from the group consisting of:
a polyimide having a structure represented by the formula (1);
a polybenzoxazole having a structure represented by the formula (3);
a polyimide precursor having a structure represented by the formula (4), wherein g in the formula (4) is 2;
a polybenzoxazole precursor having a structure represented by the formula (4), wherein g in the formula (4) is 0; or
a copolymer thereof; 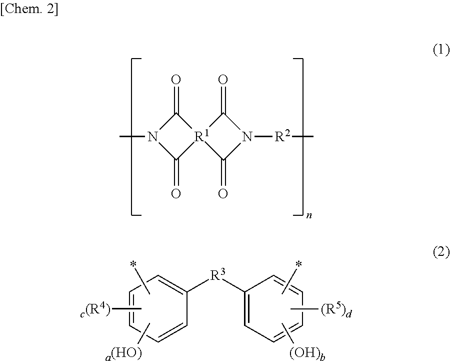
(wherein in the formula (1), R¹ represents a C₄₋₄₀ tetravalent organic group; and R² represents a structure represented by the formula (2)) and
(wherein in the formula (2), R³ represents a single bond, —O—, —C(CH₃)₂—, or —C(CF₃)₂—; R⁴ and R⁵ represent a C₁₋₂₀ monovalent organic group; a and b each independently represent an integer of 1 to 4; c and d each independently represent an integer of 0 to 1; and the sign * represents a chemical bond); 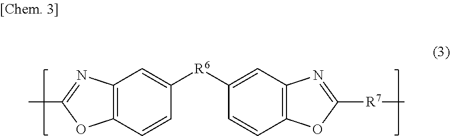
(wherein in the formula (3), R⁶ represents a single bond, —O—, —C(CH₃)₂—, or —C(CF₃)₂—; and R⁷ represents a C₄₋₄₀ divalent organic group); 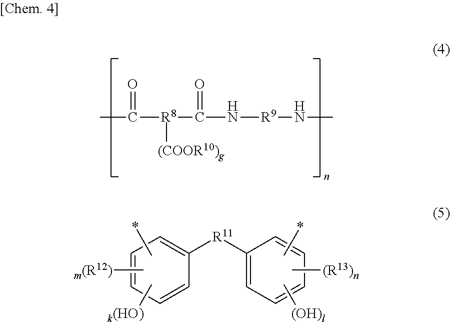
(wherein in the formula (4), R¹represents a C₄₋₄₀ divalent to tetravalent organic group; R⁹ represents a structure represented by the formula (5); R¹⁰ represents a hydrogen atom or a C₁₋₂₀ monovalent organic group; and g represents 0 or 2) and
(wherein in the formula (5), R¹¹ represents a single bond, —O—, —C(CH₃)₂—, or —C(CF₃)₂—; R¹² and R¹³ represent a C₁₋₂₀ monovalent organic group; k and l each independently represent an integer of 1 to 4; m and n each independently represent an integer of 0 to 1; and the sign * represents a chemical bond).

6. The resin composition according to claim 1, wherein R¹⁶ in the formula (6) and R¹⁸ in the formula (7) are each a structure represented by the formula (8): 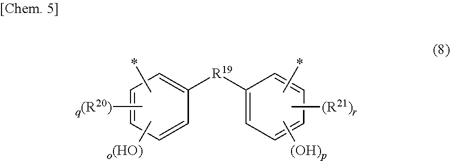
(wherein in the formula (8), R¹⁹ represents a single bond, —O—, —C(CH₃)₂—, or —C(CF₃)₂—; R²⁰ and R²¹ represent a C₁₋₂₀ monovalent organic group; o and p each independently represent an integer of 1 to 4; q and r each independently represent an integer of 0 to 1; and the sign * represents a chemical bond).

7. The resin composition according to claim 6, wherein R¹⁹ in the formula (8) is —C(CF₃)₂—.

8. A cured product obtained by curing the resin composition according to claim 1.

9. An electronic component comprising the cured product according to claim 8.

10. A display device comprising the cured product according to claim 8.
